(19) United States
(12) Patent Application Publication
(10) Pub. No.: US 2020/0083419 A1
(43) Pub. Date: Mar. 12, 2020

(54) LIGHT EMITTING DEVICE AND MANUFACTURING METHOD THEREOF

(71) Applicant: Genesis Photonics Inc., Tainan City (TW)

(72) Inventors: Yun-Han Wang, Tainan City (TW); Chin-Hua Hung, Tainan City (TW); Jui-Fu Chang, Tainan City (TW); Chuan-Yu Liu, Tainan City (TW); Yu-Feng Lin, Tainan City (TW); Cheng-Wei Hung, Changhua County (TW); Jian-Xiang Huang, Tainan City (TW); Po-Hsiang Wang, Tainan City (TW)

(73) Assignee: Genesis Photonics Inc., Tainan City (TW)

(21) Appl. No.: 16/543,648

(22) Filed: Aug. 19, 2019

Related U.S. Application Data
(60) Provisional application No. 62/719,143, filed on Aug. 17, 2018.
(60) Provisional application No. 62/863,281, filed on Jun. 19, 2019.
(60) Provisional application No. 62/873,194, filed on Jul. 12, 2019.

(51) Int. Cl. H01L 33/60; H01L 33/50; H01L 33/00; H01L 25/075

(52) U.S. Cl. CPC H01L 33/60; H01L 33/502; H01L 2933/0058; H01L 25/0753; H01L 33/0095

(57) ABSTRACT

A light emitting device including a light emitting unit, two electrodes, a reflective member, and a light transmissive member is provided. The two electrodes are disposed on one side of the light emitting unit, and electrically connected to the light emitting unit. The reflective member is disposed on the other side of the light emitting unit, and has at least one reflective surface. The light transmissive member is disposed between the reflective member and the light emitting unit, and covers a part of the light emitting unit. A lateral surface of the light transmissive member is served as a light emitting surface of the light emitting device. A manufacturing method of a light emitting device is also provided.

### CROSS-REFERENCE TO RELATED APPLICATION

This application claims the priority benefits of U.S. provisional application Ser. No. 62/719,143, filed on Aug. 17, 2018, U.S. provisional application Ser. No. 62/863,281, filed on Jun. 19, 2019, and U.S. provisional application Ser. No. 62/873,194, filed on Jul. 12, 2019. The entirety of each of the above-mentioned patent applications is hereby incorporated by reference herein and made a part of this specification.

### BACKGROUND

### Technical Field

The present invention relates to a light emitting device and a manufacturing method thereof, and particularly to a light emitting device having a reflective layer on the top of a package, and a manufacturing method thereof.

### Description of Related Art

A light emitting diode (LED) is a light emitting semiconductor electronic component, and is widely used in, for example, traffic lights, car lights, outdoor large display panels, mobile phone backlights and the like because of its advantages of high energy conversion efficiency, short response time, long life, small size, high reliability and the like. However, since the light emitting diode has the light emitting characteristic of high directivity, when it is applied to the above-mentioned fields, there is the problem of light spots generated due to excessive concentration of light, which is disadvantageous for applications in illumination and light sources.

### SUMMARY

Embodiments of the present invention provide a light emitting device which can resolve the aforementioned problem and have good illumination and light source applicability.

Embodiments of the present invention provide a manufacturing method of a light emitting device for manufacturing the above-mentioned light emitting device.

An embodiment of the present invention provides a light emitting device, including a light emitting unit, two electrodes, a reflective member, and a light transmissive member. The light emitting unit has a first side and a second side opposite to each other. The two electrodes are disposed on the first side, and the two electrodes are electrically connected to the light emitting unit. The reflective member is disposed on the second side, and the reflective member has at least one reflective surface. The light transmissive member is disposed between the reflective member and the light emitting unit, and the light transmissive member covers a part of the light emitting unit. A lateral surface of the light transmissive member is served as a light emitting surface of the light emitting device.

In an embodiment of the present invention, the light transmissive member includes a first light transmissive portion and a second light transmissive portion. The first light transmissive portion is located between the reflective member and the second light transmissive portion. The second light transmissive portion is located between the light transmissive portion and the light emitting unit. Lateral surfaces of the first light transmissive portion and the second light transmissive portion together are served as the lateral surface of the light transmissive member.

In an embodiment of the present invention, the light transmissive member further includes a third light transmissive portion. The first light transmissive portion and the second light transmissive portion cover a top surface of the light emitting unit, and the third light transmissive portion covers a lateral surface of the light emitting unit.

In an embodiment of the present invention, the light emitting device further includes a reflective protection member, disposed beside the third light transmissive portion. The reflective protection member has a reflective curved surface.

In an embodiment of the present invention, the second light transmissive portion is connected to the third light transmissive portion.

In an embodiment of the present invention, the light emitting device further includes a phosphor resin layer. The phosphor resin layer covers a top surface of the light emitting unit, and the phosphor resin layer is located between a part and another part of the light transmissive member.

In an embodiment of the present invention, the light emitting device further includes a reflective protection member, and the thickness of the reflective protection member is greater than the thickness of the light emitting unit.

In an embodiment of the present invention, the light emitting device further includes a phosphor resin layer. The reflective protection member has an accommodating space, and the accommodating space corresponds to the light emitting unit. The phosphor resin layer is disposed in the accommodating space, and the light transmissive member is disposed between the reflective member and the phosphor resin layer.

In an embodiment of the present invention, the light transmissive member includes a phosphor.

In an embodiment of the present invention, the reflective surface is a reflective inclined surface, a reflective curved surface, a reflective planar surface, or a combination thereof.

In an embodiment of the present invention, the light transmissive member covers at least a part of a top surface and a lateral surface of the light emitting unit.

An embodiment of the present invention provides a manufacturing method of a light emitting device, including the following steps: forming a reflective resin layer; providing a plurality of light emitting units, where a bottom surface of each of the light emitting units is provided with two electrodes; bonding a plurality of top surfaces of the light emitting units respectively to the reflective resin layer; forming a light transmissive resin layer, and enabling the light transmissive resin layer to cover a plurality of lateral surfaces of the light emitting units; and performing a cutting process on the reflective resin layer and the light transmissive resin layer to form a plurality of light emitting devices, where each of the light emitting devices includes at least one of the light emitting units.

In an embodiment of the present invention, after the step of forming the reflective resin layer, the manufacturing method further includes: performing a scribing process on the reflective resin layer to form a plurality of first grooves in the reflective resin layer, such that the reflective resin layer is divided into a plurality of bonding areas.

In an embodiment of the present invention, in the step of bonding the top surfaces of the light emitting units respectively to the reflective resin layer, the top surfaces are respectively bonded to the bonding areas of the reflective resin layer.

In an embodiment of the present invention, in the step of forming the light transmissive resin layer, the manufacturing method further includes: providing a light transmissive resin in the first grooves, and covering the lateral surfaces of the light emitting units; and curing the light transmissive resin to form the light transmissive resin layer.

In an embodiment of the present invention, in the step of performing the cutting process on the reflective resin layer and the light transmissive resin layer, the manufacturing method further includes: performing the cutting process on the reflective resin layer and the light transmissive resin layer along the first grooves.

In an embodiment of the present invention, the cross-sectional shape of the first grooves is an arc shape, a trapezoidal shape, a straight line, or a combination thereof.

In an embodiment of the present invention, in the step of forming the light transmissive resin layer, the manufacturing method further includes: providing a plurality of first light transmissive resins on the top surfaces of the light emitting units.

In an embodiment of the present invention, in the step of bonding the top surfaces of the light emitting units respectively to the reflective resin layer, the top surfaces are respectively bonded to the bonding areas of the reflective resin layer through the first light transmissive resins. The first light transmissive resins cover a partial surface of the reflective resin layer.

In an embodiment of the present invention, in the step of forming the light transmissive resin layer, the manufacturing method further includes: providing a plurality of second light transmissive resins around the light emitting units, and enabling the second light transmissive resins to cover the lateral surfaces of the light emitting units; and curing the first light transmissive resins and the second light transmissive resins to form the light transmissive resin layer.

In an embodiment of the present invention, in the step of forming the light transmissive resin layer, the height of the light transmissive resin layer is greater than the height of the reflective resin layer.

In an embodiment of the present invention, after the step of forming the light transmissive resin layer, the manufacturing method further includes: performing another scribing process on the light transmissive resin layer to form a plurality of second grooves in the light transmissive resin layer, such that the light transmissive resin layer is divided into a plurality of bonding areas.

In an embodiment of the present invention, the top surfaces of the light emitting units are respectively bonded to the bonding areas of the light transmissive resin layer to be indirectly bonded to the reflective resin layer.

In an embodiment of the present invention, after the step of performing the another scribing process on the light transmissive resin layer, the manufacturing method further includes: providing a plurality of reflective resins in the second grooves; and curing the reflective resins to form a plurality of reflective protection members.

In an embodiment of the present invention, in the step of performing the cutting process on the reflective resin layer and the light transmissive resin layer, the manufacturing method further includes: performing the cutting process on the reflective resin layer, the light transmissive resin layer, and the reflective protection members along the second grooves.

In an embodiment of the present invention, after the step of forming the light transmissive resin layer, the manufacturing method further includes: forming a phosphor resin layer, and enabling the phosphor resin layer to cover the light transmissive resin layer.

In an embodiment of the present invention, after the step of forming the phosphor resin layer, the top surfaces of the light emitting units are respectively bonded to the reflective resin layer through the phosphor resin layer and the light transmissive resin layer.

In an embodiment of the present invention, in the step of performing the cutting process on the reflective resin layer and the light transmissive resin layer, the cutting process is further performed on the phosphor resin layer.

In an embodiment of the present invention, in the step of forming the light transmissive resin layer, the manufacturing method further includes: providing a light transmissive resin doped with a phosphor; allowing the light transmissive resin to stand to be divided into a high-concentration phosphor resin and a low-concentration phosphor resin; and curing the high-concentration phosphor resin and the low-concentration phosphor resin, where the cured high-concentration phosphor resin is served as a phosphor resin layer, and the cured low-concentration phosphor resin is served as a first part of the light transmissive resin layer.

In an embodiment of the present invention, the manufacturing method further includes: performing a scribing process on the phosphor resin layer to form a plurality of grooves in the phosphor resin layer such that the phosphor resin layer is divided into a plurality of bonding areas.

In an embodiment of the present invention, in the step of forming the light transmissive resin layer, the manufacturing method further includes: providing a plurality of second light transmissive resins on the bonding areas.

In an embodiment of the present invention, in the step of bonding the top surfaces of the light emitting units respectively to the reflective resin layer, the top surfaces of the light emitting units are bonded to the phosphor resin layer through the second light transmissive resins to be indirectly bonded to the reflective resin layer, and the second light transmissive resins cover the lateral surfaces of the light emitting units.

In an embodiment of the present invention, in the step of forming the light transmissive resin layer, the manufacturing method further includes: curing the second light transmissive resins such that the cured second light transmissive resins are served as a part of the light transmissive resin layer.

In an embodiment of the present invention, after the step of curing the second light transmissive resins, the manufacturing method further includes: providing a plurality of reflective resins in the grooves; and curing the reflective resins to form a plurality of reflective protection members, where each of the reflective protection members surrounds the phosphor resin layer.

In an embodiment of the present invention, the light transmissive resin layer is doped with a phosphor.

Based on the above, in the light emitting device according to the embodiments of the present invention, since the reflective member and the two electrodes are respectively disposed on two opposite sides of the light emitting unit and the light transmissive member covers a part of the light emitting unit, after the light emitting unit emits a light beam, the light beam is reflected by the reflective surface of the reflective member to be emitted to the lateral surface of the light transmissive member. Therefore, the light emitting device can have the effect of lateral light emission, which can avoid the problem of light spots and have good applicability in different fields. Further, since a part of the light emitting unit is covered by the light transmissive member and is not in contact with air, the light emitting device can have a large light emitting angle. Further, in the manufacturing method of the light emitting device according to the embodiments of the present invention, since the top surface of the light emitting unit is bonded to the reflective resin layer and the lateral surface of the light emitting unit is covered by the light transmissive resin layer, the light emitting device manufactured by the above manufacturing method can avoid the problem of light spots and have a large light emitting angle.

In order to make the aforementioned and other objectives and advantages of the present invention comprehensible, embodiments accompanied with figures are described in detail below.

### BRIEF DESCRIPTION OF THE DRAWINGS

FIG. 1 to FIG. 3 are cross-sectional schematic views of a light emitting device according to different embodiments of the present invention.

FIG. 4A to FIG. 4G show a manufacturing flow chart for manufacturing the light emitting device of FIG. 1.

FIG. 5 to FIG. 7 are cross-sectional schematic views of a light emitting device according to other embodiments of the present invention.

FIG. 8A to FIG. 8H show a manufacturing flow chart for manufacturing the light emitting device of FIG. 5.

FIG. 9 to FIG. 12 are cross-sectional schematic views of the light emitting device according to other embodiments of the present invention.

FIG. 13A to FIG. 13G show a manufacturing flow chart for manufacturing the light emitting device of FIG. 9.

FIG. 14 to FIG. 17 are cross-sectional schematic views of a light emitting device according to still other embodiments of the present invention.

FIG. 18A to FIG. 18J show a manufacturing flow for manufacturing the light emitting device of FIG. 14.

FIG. 19 to FIG. 20 are cross-sectional schematic views of the light emitting device according to still other embodiments of the present invention.

FIG. 21A to FIG. 21J show a manufacturing flow for manufacturing the light emitting device of the embodiment of FIG. 19.

FIG. 22 is a schematic view showing the connection of a light emitting device of an embodiment of the present invention and a circuit substrate.

### DESCRIPTION OF THE EMBODIMENTS

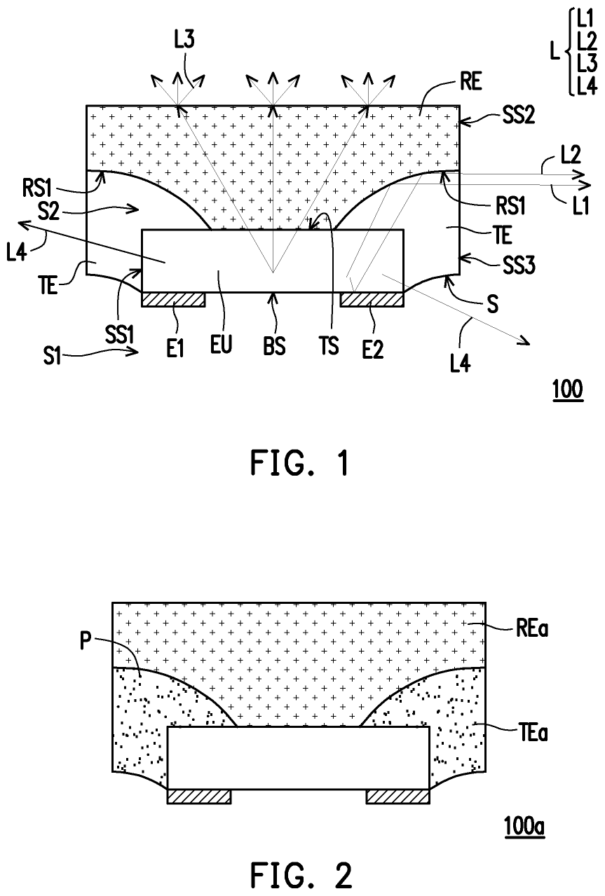

FIG. 1 to FIG. 3 are cross-sectional schematic views of a light emitting device according to different embodiments of the present invention.

Referring to FIG. 1, in the present embodiment, a light emitting device 100 includes a light emitting unit EU, two electrodes E1 and E2, a reflective member RE, and a light transmissive member TE. The disposition relationship between various elements will be described in detail in the following paragraphs.

The light emitting unit EU includes a substrate and an epitaxial laminate formed on the substrate. The epitaxial laminate includes a first type semiconductor layer, a second type semiconductor layer, and a light emitting layer (or referred to as active layer) located between the first type and second type semiconductor layers. It should be noted that only the light emitting unit EU is schematically illustrated in FIG. 1, and the structure of the epitaxial laminate and the substrate is not specifically shown. In the present embodiment, the light emitting unit EU is a blue light emitting diode. The light emitting unit EU has a top surface TS, a bottom surface BS, and a lateral surface SS1. The lateral surface SS1 is connected to the top surface TS and the bottom surface BS. In some embodiments, the bottom surface BS of the light emitting unit EU is further provided with a metal reflective layer (for example, aluminum (Al), titanium (Ti), nickel (Ni), silver (Ag) or gold (Au)) or a distributed Bragg reflector (DBR). A part of light generated by the light emitting unit EU is directly emitted through the light transmissive member TE, a part of the light enters the reflective member RE or is reflected by the reflective member RE, and the other part of the light beam L4 is reflected upward by the aforementioned metal reflective layer or the distributed Bragg reflector to the reflective member RE or is directly emitted through the light transmissive member TE.

The two electrodes E1 and E2 are disposed on the bottom surface BS of the light emitting unit EU and coupled to the light emitting unit EU, and a current can be supplied to the light emitting unit EU by the two electrodes E1 and E2 from the outside, such that the light emitting layer in the light emitting unit EU emits a light beam. The epitaxial laminate is disposed between the aforementioned electrodes E1 and E2 and the substrate. Since the bottom surface BS of the light emitting unit EU is provided with the two electrodes E1 and E2, it may also be referred to as an electrode surface. The material of the electrodes E1 and E2 is, for example, a metal material, and the selected type is, for example, chromium (Cr), aluminum (Al), titanium (Ti), nickel (Ni), platinum (Pt), gold (Au), copper (Cu), gold tin (AuSn) alloy, tin silver copper (SnAgCu) alloy, gold beryllium (AuBe) alloy, gold germanium (AuGe) alloy or a combination thereof, but is not limited thereto.

In general, the whole light emitting chip includes a light emitting unit EU and the aforementioned two electrodes E1 and E2. In the embodiments of the present invention, the light emitting chip includes, but not limited to, a blue, green, yellow, red, or ultraviolet light emitting diode chip. In the present embodiment, the light emitting chip is a blue light emitting diode chip.

The reflective member RE is, for example, generally referred to as an optical member having a reflection function. In the embodiments of the present invention, the reflective member RE may be a transflective layer, for example, powder of a transparent resin material doped with reflective particles (including but not limited to a white resin layer or a diffusion layer). In the present embodiment, the reflective member RE is, for example, a white resin layer. It should be noted that the reflective member RE is not limited to having only reflective capability, it may also have other optical effects. For example, when the reflective member RE is a white resin layer, the white resin layer may have the capabilities to partially reflect, partially scatter and transmit, and partially absorb the light beam. Specifically, the material of the white resin layer is, for example, silicone doped with a plurality of reflective particles, and the type of the material of the reflective particles includes, but not limited to, titanium dioxide (TiO2), barium sulfate (BaSO4) or other white reflective particles. Furthermore, the reflective member RE has at least one reflective surface RS1 and a lateral surface SS2, and the lateral surface SS2 is connected to the reflective surface RS1. In the present embodiment, the reflective member RE has two reflective surfaces RS1, and the reflective surface RS1 is, for example, a curved surface. In other embodiments the reflective surface RS1 may be a planar surface. The reflective surface RS1 can reflect a part of the light beam generated by the light emitting unit EU and then emit light through the light transmissive member TE, and its optical effects will be described in detail in the following paragraphs.

The light transmissive member TE is, for example, an optical member which can transmit a light beam. In the present embodiment, the light transmissive member TE includes, but not limited to, a light transmissive resin layer or a light transmissive resin layer having scattering particles. The light transmissive member TE has a lateral surface SS3 and an outwardly exposed lower surface S. The lower surface S is connected to the lateral surface SS3 and the light emitting chip (the light emitting unit EU and/or the electrodes E1 and E2). In the present embodiment, the lower surface S is an inwardly concave curved surface. In other embodiments, the lower surface S may be a planar surface or an outwardly convex curved surface. The light beam generated by the light emitting unit EU can be emitted through the lateral surface SS3 or the lower surface S of the light transmissive member TE, and its optical effects will be described in detail in the following paragraphs.

The disposition relationship between elements in the light emitting device 100 of the present embodiment will be described in detail in the following paragraphs.

Referring to FIG. 1, the light emitting unit EU has opposite first and second sides S1 and S2. The two electrodes E1 and E2 are disposed on the same side (for example, the first side S1) of the light emitting unit EU. The two electrodes E1 and E2 are in contact with the bottom surface BS of the light emitting unit EU. The reflective member RE is disposed on the second side S2 and is in contact with the top surface TS of the light emitting unit EU. The two reflective surfaces RS1 of the reflective member RE are also located on the second side S2 of the light emitting unit EU. In other words, the reflective member RE and the two electrodes E1 and E2 are respectively disposed on different sides S1 and S2 of the light emitting unit EU. The light transmissive member TE covers a part of the light emitting unit EU and, for example, covers the partial top surface TS and the lateral surface SS1 of the light emitting unit EU. Further, in the present embodiment, one lateral surface of the light emitting device 100 includes the lateral surface SS2 of the reflective member RE and the lateral surface SS2 of the light transmissive member TE, and the lateral surface of the aforementioned light emitting device 100 is a substantially flat surface.

The technical effects of the light emitting device 100 of the present embodiment will be described in detail in the following paragraphs.

In the light emitting device 100 of the present embodiment, the different sides S1 and S2 of the light emitting unit EU are respectively provided with the reflective member RE and the two electrodes E1 and E2, the light transmissive member TE is disposed between the light emitting unit and the reflective member RE, and the light transmissive member TE covers a part of the light emitting unit EU. Thus, after the light emitting unit EU emits the light beam L, a part of the light beam L1 is emitted from the top surface TS thereof and then enters the light transmissive member TE, and is then reflected by the reflective surface RS to be emitted through the lateral surface SS3 of the light transmissive member TE. A part of the light beam L2 is emitted to the electrodes E1 and E2, is reflected by the electrode E2 (or E1) to the reflective surface RS1, and is then reflected by the reflective surface RS to be emitted through the lateral surface SS3 of the light transmissive member TE. Therefore, the light emitting device 100 of the present embodiment can have the effect of lateral light emission, thereby avoiding the problem of light spots derived from the concentrated emission of the light beam.

Besides, since the reflective member RE of the present embodiment is a transflective layer (including but not limited to a white resin layer or a material layer containing diffusing particles), a part of the light beam L3 will penetrate the reflective member RE and be scattered by the reflective particles therein, and will be emitted to the upper side of the light emitting device 100. Since the light beam L3 is scattered, it is also possible to avoid the problem of light spots derived from the excessive concentration of the light beam.

Further, in the light emitting device 100 of the present embodiment, since the light transmissive member TE covers the partial top surface TS and the lateral surface SS1 of the light emitting unit EU, the light emitting unit EU is not directly in contact with air, and the light emitting device 100 can have a large light emitting angle. Besides, the light emitting area of the light emitting device 100 can be adjust by adjusting the area of the lateral surface SS1 of the light transmissive member TE. A part of the light beam L4 generated by the light emitting unit EU can also be emitted via the lateral surface SS3 or the lower surface S of the light transmissive member TE.

Based on the above, the light emitting device 100 of the present embodiment avoids the problem of light spots derived from excessive concentration of light emission, and therefore, has good applicability.

It is worth mentioning that, in the present embodiment, the types of the two reflective surfaces RS1 are, for example, reflective curved surfaces. In other embodiments, it is also possible that one is a reflective curved surface, and the other is a reflective inclined surface, a reflective planar surface parallel to the top surface of the light emitting unit, or another reflective surface of a different shape, and the present invention is not limited thereto.

It should be noted herein that the following embodiments use some of the foregoing embodiments, and the descriptions of identical technical content are omitted. For the same element names, reference may be made to partial contents of the foregoing embodiments, and the descriptions thereof are omitted in the following embodiments. Besides, in the following drawings, only the element numbers that are different from the above embodiments and that are related to technical contents mentioned in the following paragraphs are shown.

Referring to FIG. 2, a light emitting device 100a of FIG. 2 is substantially similar to the light emitting device 100 of FIG. 1. The major difference is that: in the light emitting device 100a, a light transmissive member TEa is doped with a phosphor P. In the present embodiment, the phosphor P is, for example, a yellow light phosphor, a red light phosphor, a green light phosphor, or a phosphor capable of being excited to emit light in another different color, and the present invention is not limited thereto. In the present embodiment, the phosphor P is a yellow light phosphor. Since the light beam (not shown) emitted by the light emitting unit EU is blue light, when the light beam passes through the light transmissive member TEa, a part of the light beam excites the phosphor P to generate yellow light, and the yellow light is combined with another part of the light beam to emit white light.

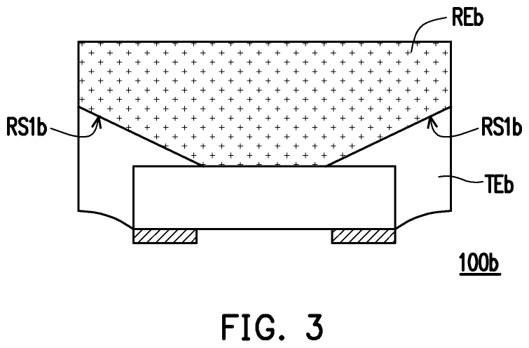

Referring to FIG. 3, a light emitting device 100b of FIG. 3 is substantially similar to the light emitting device 100 of FIG. 1. The major difference is that: in the light emitting device 100b, a reflective surface RS1b of a reflective member REb is a substantially flat inclined surface. Further, the light transmissive member TEb is slightly different in shape from the light transmissive member TE because the reflective member REb is different in shape from the reflective member RE.

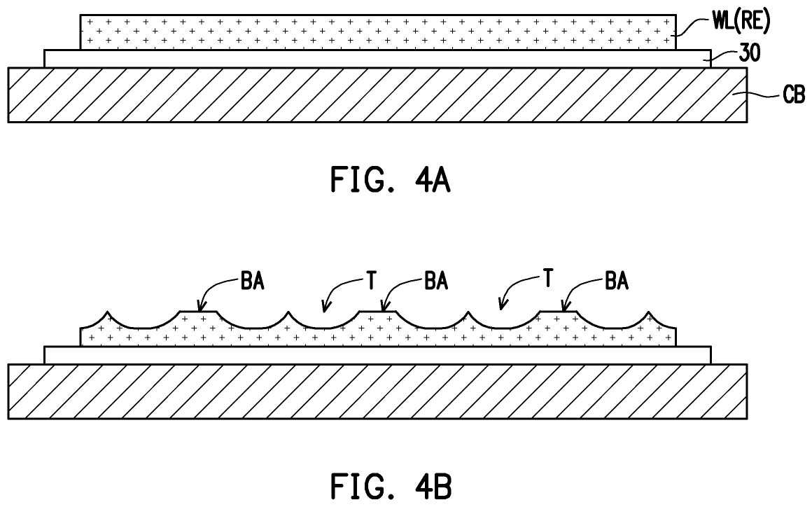

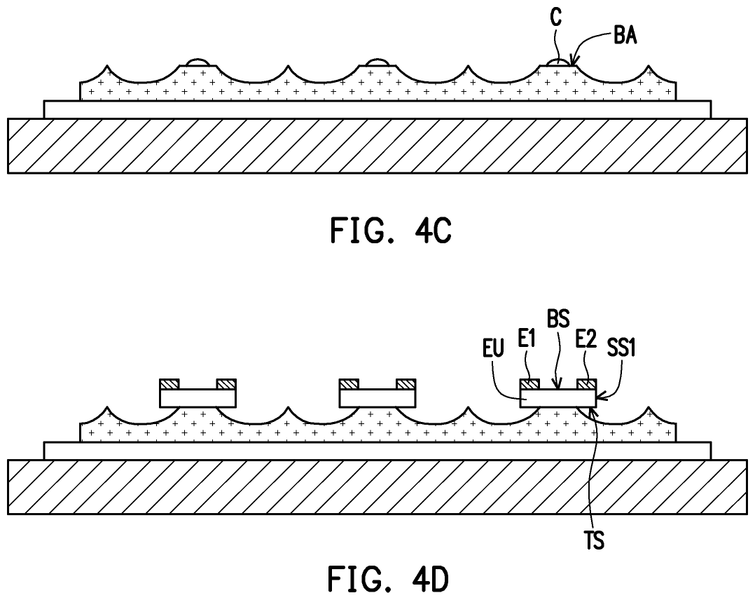

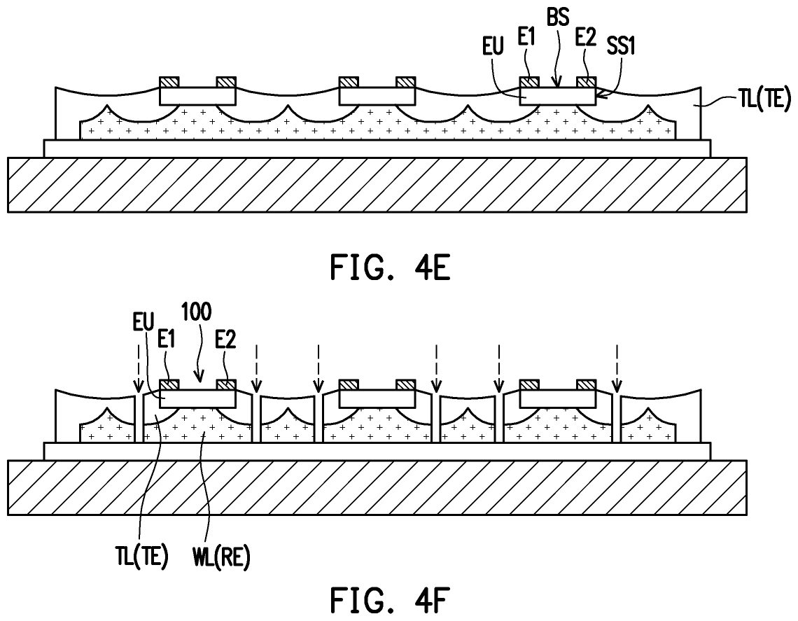

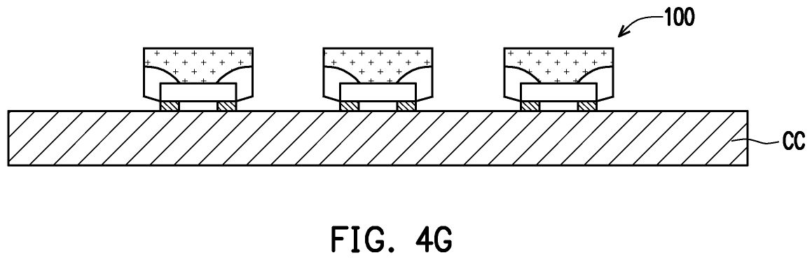

FIG. 4A to FIG. 4G show a manufacturing flow chart for manufacturing the light emitting device of FIG. 1.

Referring to FIG. 4A, a carrier substrate CB is provided, a release film 30 and a white resin layer WL (which can be regarded as a reflective resin layer) are sequentially formed on the carrier substrate CB, and the white resin layer WL is heated and baked, such that the white resin layer WL is cured and set. The white resin layer WL is served as the reflective member RE of FIG. 1.

Referring to FIG. 4B, a scribing process is performed on the cured white resin layer WL to form a plurality of grooves T, such that the cured white resin layer WL is divided into a plurality of bonding areas BA (or referred to as platform areas). In detail, the scribing process described above, for example, scribes two grooves T having curved surfaces between two adjacent bonding areas BA. A scribing tool used in the scribing process is, for example, an arc scribing knife, and thus, can scribe the reflective curved surface as in FIG. 1 during scribing, but is not limited thereto. In addition, it should be noted that it is not necessary to use the same tool in the scribing process. In some embodiments, an arc scribing knife and an inclined surface scribing knife may also be used, so that a reflective curved surface, a reflective inclined surface or a combination of a curved surface and an inclined surface as in FIG. 1 and FIG. 2 can be scribed during scribing, but the present invention is not limited thereto.

Referring to FIG. 4C, a plurality of die bonding adhesives C are respectively provided on the bonding areas BA, and the die bonding adhesives C are provided on the bonding areas BA, for example, by dispensing. The die bonding adhesive C is, for example, a transparent adhesive layer.

Referring to FIG. 4D, a plurality of light emitting units EU are provided. A bottom surface BS of each of the light emitting units EU is provided with two electrodes E1 and E2. A top surface TS of each of the light emitting units EU is bonded to the corresponding bonding area BA through the die bonding adhesive C. In the present embodiment, the manner of providing the light emitting unit EU is, for example, to pick up the light emitting units EU one by one and bond them to the corresponding bonding areas BA, but is not limited thereto. In other embodiments, another carrier substrate provided with a release film may also be provided, and the electrodes of the light emitting units are bonded to the release film to expose the top surfaces of the light emitting units. Besides, the light emitting units are transferred to the bonding areas through the carrier substrate, and the carrier substrate is removed to implement a many-to-many (i.e., a plurality of light emitting units and a plurality of bonding areas) transfer step. A plurality of light emitting units may be placed on the carrier substrate, then the plurality of light emitting units are connected to the corresponding bonding areas BA at one time, the plurality of light emitting units are bonded to the white resin layer WL via the die bonding adhesives C, the two electrodes are disposed upward, and are located on one side of the plurality of light emitting units opposite to the white resin layer WL.

Referring to FIG. 4E, a light transmissive resin fills around the light emitting units EU, and the light transmissive resin is allowed to stand. The light transmissive resin after standing will form a downwardly concave curved surface, and the light transmissive resin is heated and baked to form a light transmissive resin layer TL. The light transmissive resin layer TL covers the lateral surface SS1 of each of the light emitting units EU, and exposes the bottom surface BS of each of the light emitting units EU and the two electrodes E1 and E2. The light transmissive resin layer TL is served as the light transmissive member TE of FIG. 1.

Referring to FIG. 4F, a cutting process is performed on the light transmissive resin layer TL and the white resin layer WL, and the light transmissive resin layer TL and the white resin layer WL are cut through to form a plurality of light emitting devices 100 separated from each other. Each of the light emitting devices 100 includes at least one light emitting unit EU, two electrodes E1 and E2, a reflective member RE, and a light transmissive member TE. The architecture of the light emitting device 100 is as described in the above paragraphs, and the descriptions thereof are omitted herein.

Referring to FIG. 4G, a carrier resin film CC is provided. The carrier substrate CB of FIG. 4F is inverted to bond (temporarily adhere) the separated light emitting devices 100 to the carrier resin film CC. The carrier resin film CC is removed. Thus, the manufacturing of the light emitting device 100 is completed.

In addition, if the light emitting device 100a as shown in FIG. 2 is to be manufactured, the manufacturing process is substantially similar to that of the light emitting device 100, and the major difference is that: in FIG. 4E, a phosphor resin doped with a phosphor P fills around the light emitting units EU, and the phosphor resin is heated and baked to form a phosphor resin layer. Other processes are similar to the manufacturing process of the light emitting device 100, and the descriptions thereof are omitted herein.

In addition, if the light emitting device 100b as shown in FIG. 3 is to be manufactured, the manufacturing process is substantially similar to that of the light emitting device 100, and the major difference is that: in the scribing process of FIG. 2B, a scribing tool used is, for example, an inclined surface scribing knife, so that a reflective inclined surface as in FIG. 2 can be scribed during the scribing. Other processes are similar to the manufacturing process of the light emitting device 100, and the descriptions thereof are omitted herein.

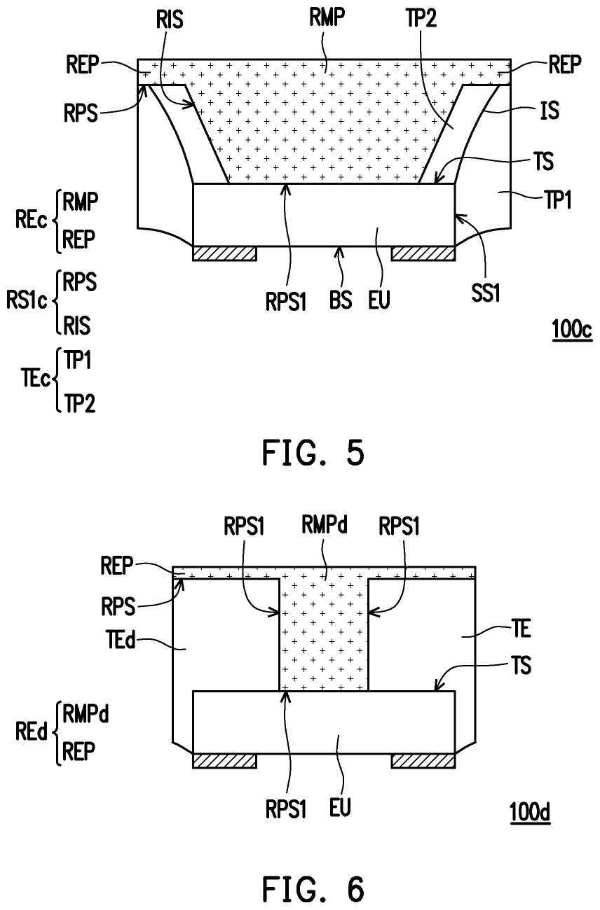

FIG. 5 to FIG. 7 are cross-sectional schematic views according to other embodiments of the present invention.

Referring to FIG. 5, a light emitting device 100c of FIG. 5 is substantially similar to the light emitting device 100 of FIG. 1. The major difference is that: in the light emitting device 100c, a reflective member REc includes a reflective main portion RMP and a reflective extending portion REP extending from two sides thereof. The reflective main portion RMP is in contact with the light emitting unit EU, and the reflective extending portion REP is isolated from the light emitting unit EU by first and second light transmissive portions TP1 and TP2 of a light transmissive member TEc. The reflective main portion RMP is substantially a trapezoidal cylinder and has a reflective inclined surface RIS, and the reflective extending portion REP has a reflective planar surface RPS. A reflective surface RS1c of the reflective member REc includes a reflective planar surface RPS and a reflective inclined surface RIS. The reflective inclined surface RIS is inclined with respect to the reflective planar surface RPS, and the reflective planar surface RPS is parallel to the top surface TS of the light emitting unit EU.

In another aspect, the light transmissive member TEc includes first and second light transmissive portions TP1 and TP2. The first light transmissive portion TP1 is in contact with the lateral surface SS1 of the light emitting unit EU, and the second light transmissive portion TP2 is located among the reflective member REc, the light transmissive portion TP1, and the light emitting unit EU, and is in contact with the top surface TS of the light emitting unit EU. Besides, an interface IS is formed between the first and second light transmissive portions TP1 and TP2.

Referring to FIG. 6, a light emitting device 100d of FIG. 6 is substantially similar to the light emitting device 100c of FIG. 5. The major difference is that: in the light emitting device 100c, a reflective member Red includes a reflective main portion RMPd and a reflective extending portion REP extending from two sides thereof. The reflective main portion RMPd is substantially a rectangular parallelepiped and has a reflective planar surface RPS1 perpendicular to the top surface TS of the light emitting unit EU. The reflective planar surface RPS1 is perpendicular to the top surface TS of the light emitting unit EU. A reflective surface RS1d of the reflective member REd includes a reflective planar surface RPS and a reflective planar surface RPS1. Further, a light transmissive member TEd is slightly different in shape from the light transmissive member TEc because the reflective member REd is different in shape from the reflective member REc of FIG. 5.

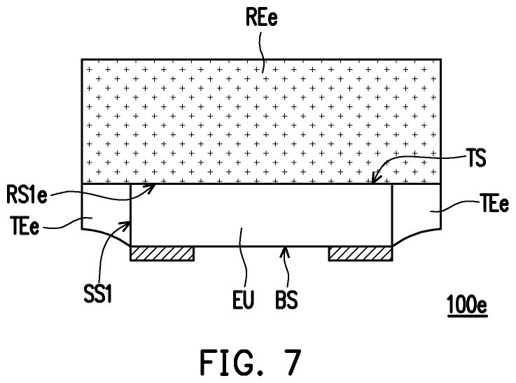

Referring to FIG. 7, a light emitting device 100e of FIG. 7 is substantially similar to the light emitting device 100 of FIG. 1. The major difference is that: in the light emitting device 100e, a reflective member REe covers the light emitting unit EU and a reflective member REe, and a reflective surface RS1e of the reflective member REe is attached to the top surface TS of the light emitting unit EU and a top surface of the reflective member REe. The light transmissive member TEe covers the lateral surface SS1 of the light emitting unit EU. Further, the light transmissive member TEe is slightly different in shape from the light transmissive member TEc because the reflective member REe is different in shape from the reflective member REc of FIG. 5.

Based on the above, in the light emitting devices 100c-100e of FIG. 5 to FIG. 7, the light emitting effect is similar to that of FIG. 1, and the major difference is that: light emitting paths are different since the reflective surfaces RS1c-RS1e in the light emitting devices 100c-100e are different in form.

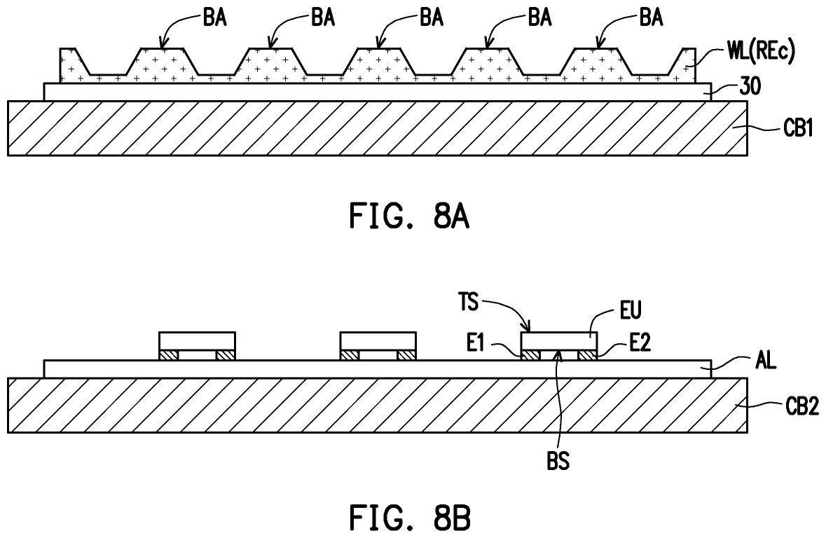

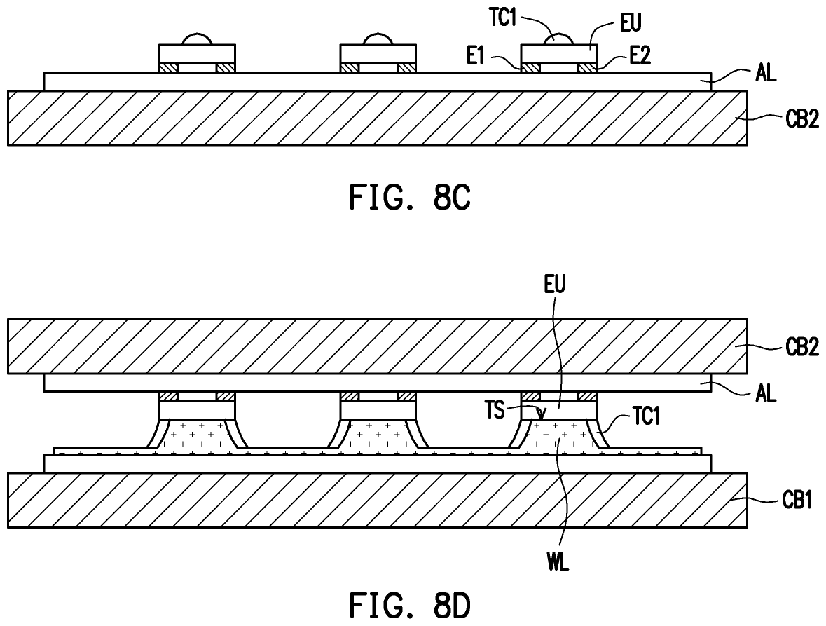

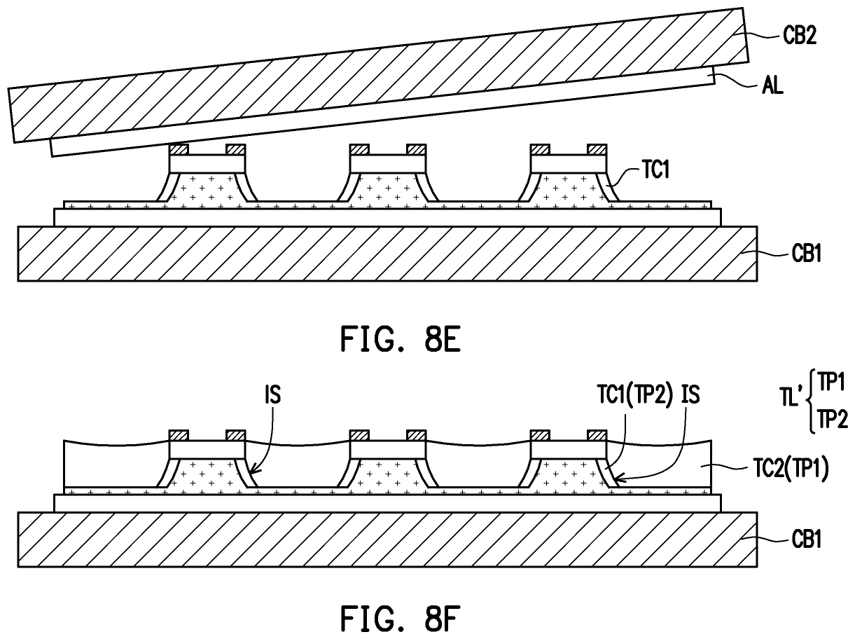

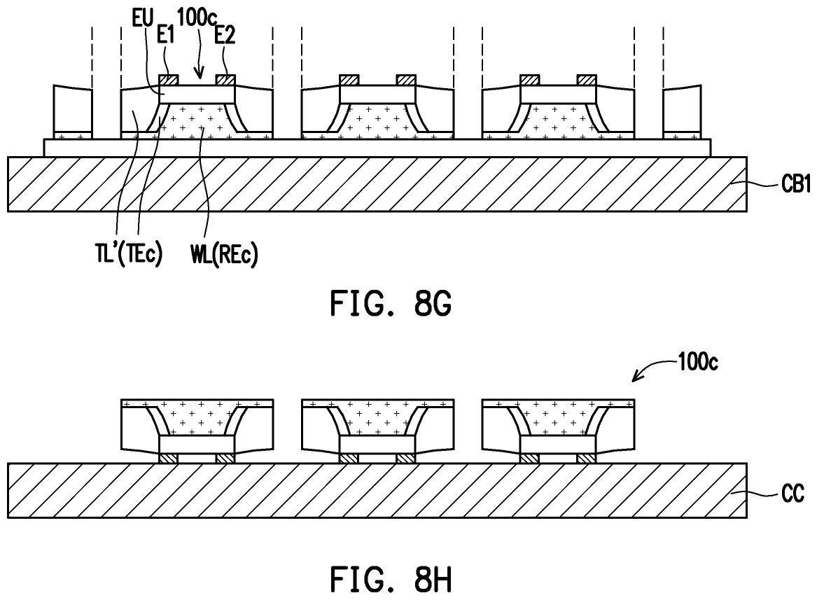

FIG. 8A to FIG. 8G show a manufacturing flow chart for manufacturing the light emitting device of FIG. 5.

Referring to FIG. 8A, a first carrier substrate CB1 is provided, a release film 30 and a white resin layer WL are sequentially formed on the first carrier substrate CB1, and the white resin layer WL is heated and baked, such that the white resin layer WL is cured and set. The white resin layer WL is served as the reflective member REc of FIG. 5. Further, a scribing process is performed on the cured white resin layer WL to scribe a plurality of grooves T, such that the white resin layer WL is divided into a plurality of bonding areas BA (or referred to as platform areas). Between every two adjacent bonding areas BA, for example, one groove T is provided. The groove T is, for example, a trapezoidal groove. A scribing tool used in the scribing process is, for example, a trapezoidal scribing knife, but is not limited thereto.

Referring to FIG. 8B, a second carrier substrate CB2 is provided, and an adhesive layer AL is formed on the second carrier substrate CB1. A plurality of light emitting units EU are provided, electrodes E1 and E2 on each of the light emitting units EU are regularly arranged and adhered to the adhesive layer AL, and a top surface TS of the light emitting unit EU is exposed upward. The distance between the adjacent two light emitting units EU arranged on the adhesive layer AL corresponds to the distance between the two adjacent bonding areas BA.

Referring to FIG. 8C, a plurality of light transmissive resins TC1 are provided on the top surfaces TS of the light emitting units EU.

Referring to FIG. 8D, the second carrier substrate CB2 is inverted to the upper side of the first carrier substrate CB1, and the plurality of top surfaces TS of the light emitting units EU are respectively bonded to the bonding areas BA. Because of squeezing, the light transmissive resin TC1 overflows to two sides of the bonding area BA to cover a part of an inclined surface of the white resin layer WL.

Referring to FIG. 8E, the second carrier substrate CB2 and the adhesive layer AL are removed.

Referring to FIG. 8F, a light transmissive resin TC2 fills around the light emitting units EU, and after the light transmissive resin TC2 is allowed to stand, the light transmissive resin TC2 forms a concave surface. Next, the light transmissive resins TC1 and TC2 are heated and baked to form a light transmissive resin layer TL′. Since the light transmissive resins TC1 and TC2 are manufactured in different steps, an interface IS is formed between the two light transmissive resins TC1 and TC2. The cured light transmissive resin TC1 is served as the second light transmissive portion TP2 of FIG. 5, and the cured light transmissive resin TC2 is served as the first light transmissive portion TP1 of FIG. 5.

Referring to FIG. 8G, a cutting process is performed on the light transmissive resin layer TL′ and the white resin layer WL, and the light transmissive resin layer TL and the white resin layer WL are cut through to form a plurality of light emitting devices 100c separated from each other. Each of the light emitting devices 100c includes at least one light emitting unit EU, a reflective member REc, two electrodes E1 and E2, and a light transmissive member TEc. The architecture of the light emitting device 100c is as described in the above paragraphs, and the descriptions thereof are omitted herein.

Referring to FIG. 8H, a carrier resin film CC is provided. The first carrier substrate CB1 is inverted to bond the separated light emitting devices 100c to the carrier resin film CC. Thus, the manufacturing of the light emitting device 100 is completed.

In addition, if the light emitting device 100d is to be manufactured, the manufacturing process is substantially similar to that of the light emitting device 100c, and the major difference is that: in the scribing step of FIG. 8A, the cured white resin layer WL may be scribed with a rectangular scribing knife to scribe a plurality of rectangular cuts. Other processes are similar to the manufacturing process of the light emitting device 100c, and the descriptions thereof are omitted herein.

In addition, if the light emitting device 100e shown in FIG. 7 is to be manufactured, the manufacturing process is substantially similar to that of the light emitting device 100c, and the major difference is that: the scribing step is not performed on the cured white resin layer WL in FIG. 8A. Therefore, the cured white resin layer WL has a substantially flat upper surface. Other processes are similar to the manufacturing process of the light emitting device 100c, and the descriptions thereof are omitted herein.

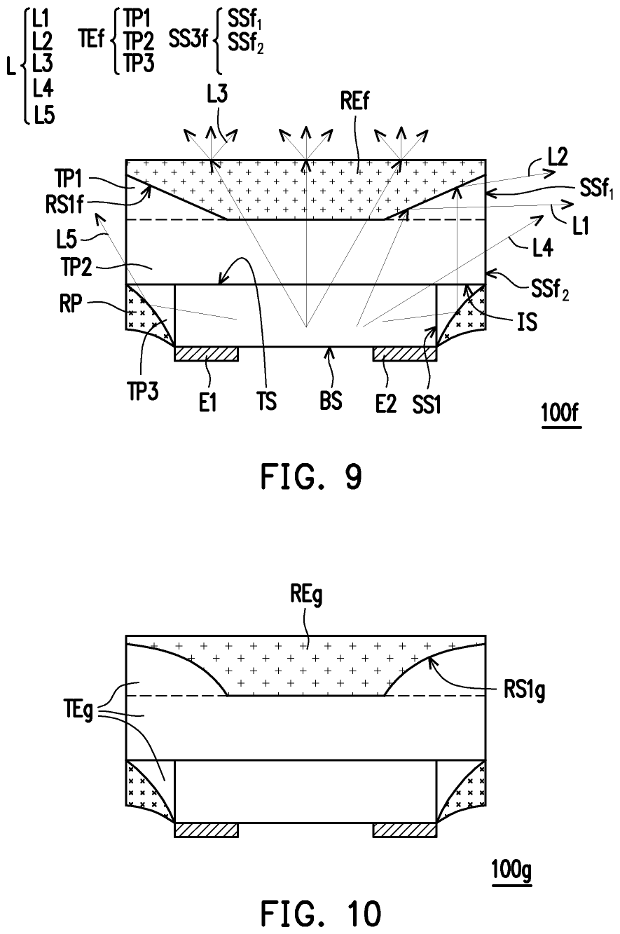

FIG. 9 to FIG. 12 are cross-sectional schematic views of the light emitting device according to other embodiments of the present invention.

Referring to FIG. 9, a light emitting device 100f of FIG. 9 is substantially similar to the light emitting device 100 of FIG. 1. The major difference is that: in the light emitting device 100f, a reflective protection member RP is further included. Besides, a light transmissive member TEf includes first, second, and third light transmissive portions TP1-TP3 connected to each other. The first and second light transmissive portions TP1 and TP2 are integrally formed, and an interface IS is formed between the second light transmissive portion TP2 and the third light transmissive portion TP3. The first light transmissive portion TP1 is located between the reflective member RE and the second light transmissive portion TP2, and is in contact with a reflective member REf. The second light transmissive portion TP2 is located between the first light transmissive portion TP1 and the light emitting unit EU, and is in contact with the top surface TS of the light emitting unit EU. The third light transmissive portion TP3 is located between the light emitting unit EU and the reflective protection member RP. Lateral surfaces SSf1 and SSf2 of the first and second light transmissive portions TP1 and TP2 together are served as a lateral surface SS1f of the light transmissive member TEf. Further, in the present embodiment, the reflective surface RS1f is a substantially flat inclined surface.

Based on the above, in the light emitting device 100f of the present embodiment, the second light transmissive portion TP2 is disposed between the first light transmissive portion TP1 in the light transmissive member TEf and the light emitting unit EU, and the area of a lateral surface SS3f (i.e., a light emitting surface) of the light transmissive member TEf can be further increased.

In addition, in the present embodiment, the light emitting path is slightly different from that of FIG. 1. After the light emitting unit EU emits the light beam L, a part of the light beam L1 sequentially enters the second light transmissive portion TP2 and the first light transmissive portion TP1 from the top surface TS, is then reflected by the reflective surface RS1, and is emitted through the lateral surface SS3f of the light transmissive member TEf. Another part of the light beam L2 enters the third light transmissive portion TP3 from the lateral surface SS1, is reflected by the reflective protection member RP to sequentially enter the second light transmissive portion TP2 and the first light transmissive portion TP1, is then reflected by the reflective surface RS1, and is emitted through the lateral surface SS3f of the light transmissive member TEf. A part of the light beam L4 in the light beam L is emitted through the second light transmissive portion TP2, and another part of the light beam L5 is reflected by the reflective protection member RP, passes through the interface IS of the second and third light transmissive portions TP2 and TP3, and is then emitted through the lateral surface of the first or second light transmissive portion TP1 or TP2. In the present embodiment, a lateral surface of the light emitting device 100f includes a reflective member REf, a light transmissive member TEf, and a reflective protection member RP, and the lateral surface of the light emitting device 100f is a substantially flat surface.

Referring to FIG. 10, a light emitting device 100g of FIG. 10 is substantially similar to the light emitting device 100f of FIG. 9. The major difference is that: in the light emitting device 100g, a reflective surface RS1g of a reflective member REg is a reflective curved surface. Further, a light transmissive member TEg is slightly different in shape from the light transmissive member TEf because the reflective member REg is different in shape from the reflective member REf of FIG. 9.

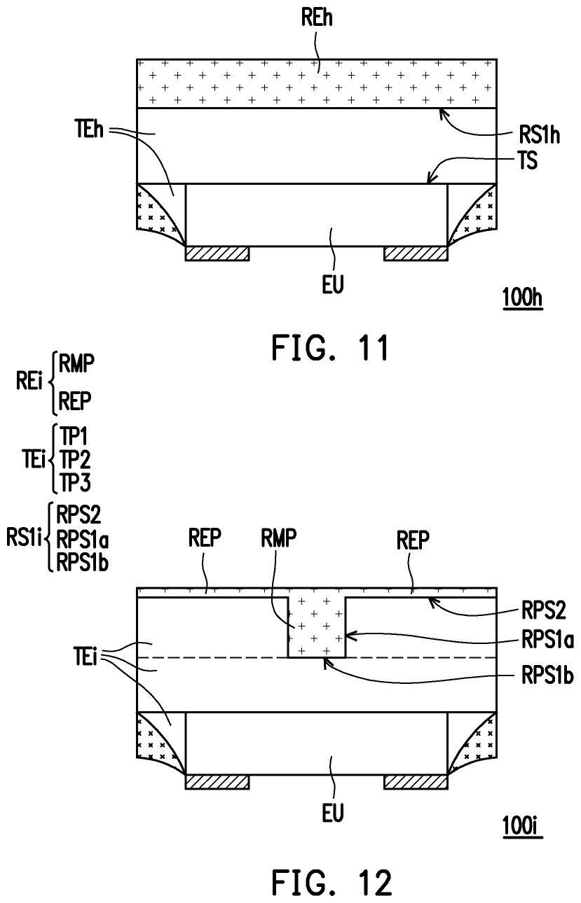

Referring to FIG. 11, a light emitting device 100h of FIG. 11 is substantially similar to the light emitting device 100f of FIG. 9. The major difference is that: in the light emitting device 100h, a reflective surface RS1h of a reflective member REh is a reflective planar surface parallel to the top surface TS of the light emitting unit EU. Further, a light transmissive member TEh is slightly different in shape from the light transmissive member TEf because the reflective member REh is different in shape from the reflective member REf of FIG. 9.

Referring to FIG. 12, a light emitting device 100i of FIG. 12 is substantially similar to the light emitting device 100f of FIG. 9. The major difference is that: in the light emitting device 100i, a reflective member REi includes a reflective main portion RMPi and a reflective extending portion REP extending from two sides thereof. The reflective main portion RMP protrudes in a direction toward the light emitting unit EU with respect to the reflective extending portion REP. The reflective main portion RMPi is substantially a rectangular cylinder and has reflective planar surfaces RPS1a and RPS1b, and the reflective extending portion REP has a reflective planar surface RPS2. A reflective surface RS1i of the reflective member REi includes reflective planar surfaces RPS1a, RPS1b and RPS2. The reflective planar surfaces RPS1b and RPS2 are parallel to the top surface TS of the light emitting unit EU, and the reflective planar surface RPS1a is perpendicular to the top surface TS of the light emitting unit EU. Further, the light transmissive member TEg is slightly different in shape from the light transmissive member TEf because the reflective member REg is different in shape from the reflective member REf of FIG. 9. Further, the light transmissive member TEi is slightly different in shape from the light transmissive member TEf because the reflective member REi is different in shape from the reflective member REf of FIG. 9.

Based on the above, in the light emitting devices 100g-100i of FIG. 10 to FIG. 12, the light emitting effect is similar to that of FIG. 9, and the major difference is that: light emitting paths are different since the reflective surfaces RS1g-RS1i in the light emitting devices 100g-100i are different in form.

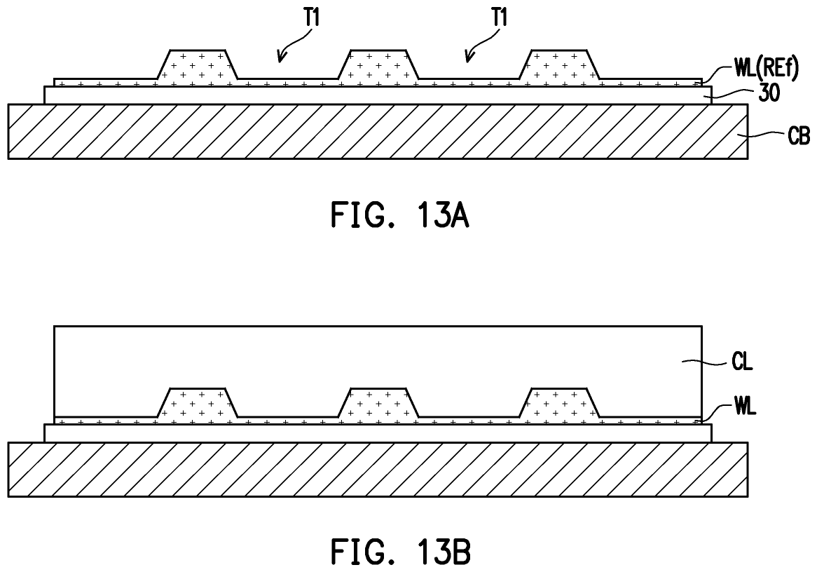

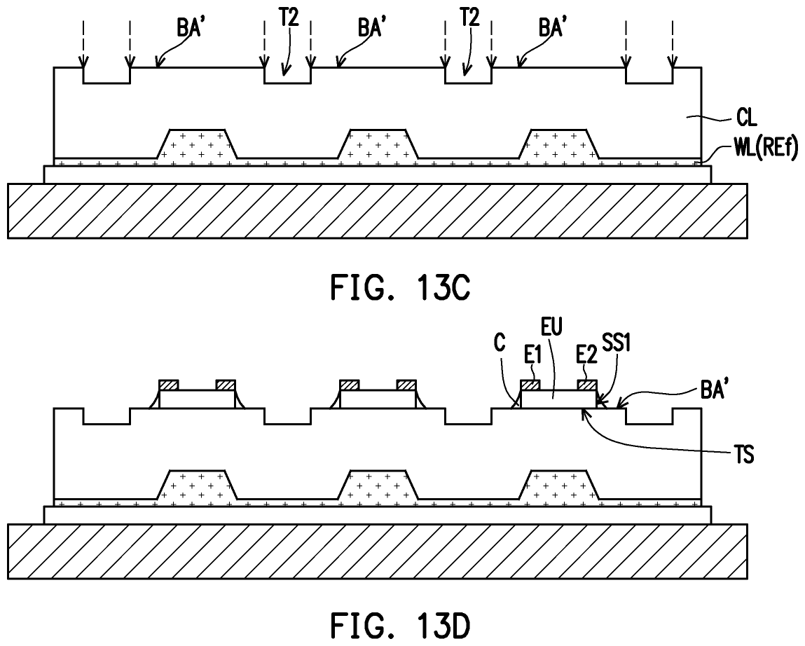

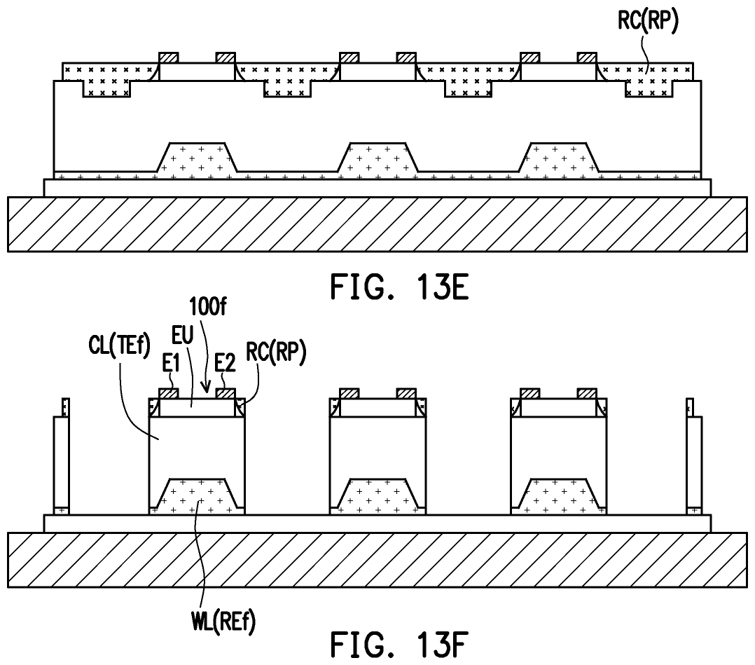

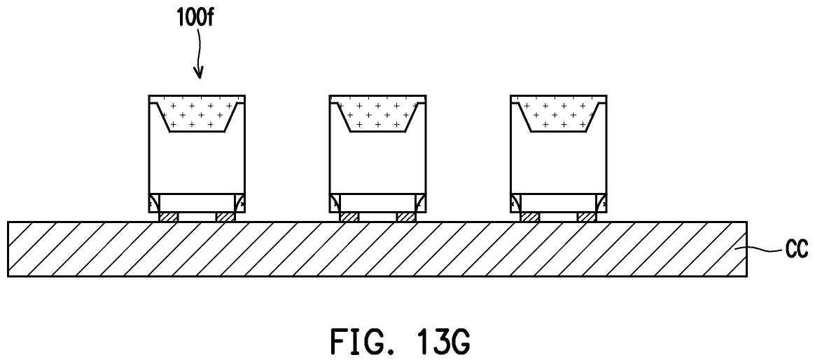

FIG. 13A to FIG. 13G show a manufacturing flow chart for manufacturing the light emitting device of FIG. 9.

Referring to FIG. 13A, a carrier substrate CB is provided, a release film 30 and a white resin layer WL are sequentially formed on the carrier substrate CB, and the white resin layer WL is heated and baked, such that the white resin layer WL is cured and set. Besides, a first scribing process is performed on the cured white resin layer WL to scribe a plurality of grooves T1, such that the cured white resin layer WL is divided into a plurality of bonding areas BA (or referred to as platform areas), and the white resin layer WL between the two grooves T is served as the reflective member REf as shown in FIG. 9. A scribing tool used in the scribing process is, for example, a trapezoidal scribing knife, but is not limited thereto.

Referring to FIG. 13B, a light transmissive resin layer CL is formed on the cured white resin layer WL, and the height of the light transmissive resin layer CL is greater than the height of the white resin layer WL. In detail, a light transmissive resin is firstly provided on the white resin layer WL, such that the light transmissive resin is higher than the white resin layer WL, and then the light transmissive resin is cured to form the light transmissive resin layer CL. The height of the light transmissive resin layer CL can be adjusted as a light flux for controlling the light receiving of the light emitting device, and a proper number of the light transmissive resin is dripped on the white resin layer WL according to different product applications, so as to increase the light receiving effect.

Referring to FIG. 13C, a second scribing process is performed on the light transmissive resin layer CL to scribe a plurality of grooves T2, such that the cured white resin layer WL is divided into a plurality of bonding areas BA′ (or referred to as platform areas). Each of the bonding areas BA′ corresponds to a reflective member REf.

Referring to FIG. 13D, a plurality of die bonding adhesives C (the die bonding adhesives C are, for example, transparent glue) are respectively provided on the bonding areas BA′, and the die bonding adhesives are provided on the bonding areas BA′, for example, by dispensing. Next, a plurality of light emitting units EU are provided, a top surface TS of each of the light emitting units EU is bonded to the corresponding bonding area BA′ through the die bonding adhesive C, and electrodes E1 and E2 face toward the outside. The die bonding adhesive C covers the lateral surface SS1 of the light emitting unit EU and forms a curved surface. Next, the die bonding adhesives C are baked to be cured. Further, in other embodiments, another carrier substrate provided with a release film may also be provided, and the electrodes of the light emitting units are bonded to the release film to expose the top surfaces thereof. Next, the die bonding adhesives are formed on the top surfaces of the light emitting units. Further, the carrier substrate loaded with the light emitting units is transferred to the bonding areas BA′, and the carrier substrate is removed. The plurality of light emitting units are disposed on the carrier substrate, and an adhering and bonding process is performed on the light emitting units and the corresponding bonding areas BA′, so that the light emitting units are transferred to the bonding areas BA′ of the white resin layer WL at one time, thereby avoiding the problem of chip skew or incomplete bonding due to the use of a single chip to be fixed on the corresponding bonding area BA′.

Referring to FIG. 13E, a reflective resin RC fills around the light emitting units EU, and the reflective resin RC is heated and baked to be cured. The reflective resin RC is served as a reflective protection member RP as in FIG. 9.

Referring to FIG. 13F, a cutting process is performed on the cured reflective resins RC, the light transmissive resin layer CL, and the cured white resin layer WL to cut through the reflective resins RC, the light transmissive resin layer CL, and the white resin layer WL corresponding to the grooves T2, and a cut surface penetrates the reflective resins RC, the light transmissive resin layer CL, and the white resin layer WL to form a flat lateral surface, so as to form a plurality of light emitting devices 100f separated from each other. Each of the light emitting devices 100f includes at least one light emitting unit EU, a reflective member REf, a light transmissive member TEf, two electrodes E1 and E2, and a reflective protection member RP. The architecture of the light emitting device 100f is as described in the above paragraphs, and the descriptions thereof are omitted herein.

Referring to FIG. 13G, a carrier resin film CC is provided. The carrier substrate CB is inverted to bond the separated light emitting devices 100f to the carrier resin film CC. Thus, the manufacturing of the light emitting device 100f is completed.

In addition, if the light emitting devices 100g-100i are to be manufactured, the manufacturing process is substantially similar to that of the light emitting device 100f, and the major difference is that: in the first scribing process of FIG. 13A, different forms of scribing tools are adopted, or no scribing is performed. For example, if the light emitting device 100g is to be manufactured, an arc scribing knife is adopted. If the light emitting device 100h is to be manufactured, no scribing is performed. If the light emitting device 100i is to be manufactured, a rectangular scribing knife is adopted. Other processes are similar to the manufacturing process of the light emitting device 100f, and the descriptions thereof are omitted herein.

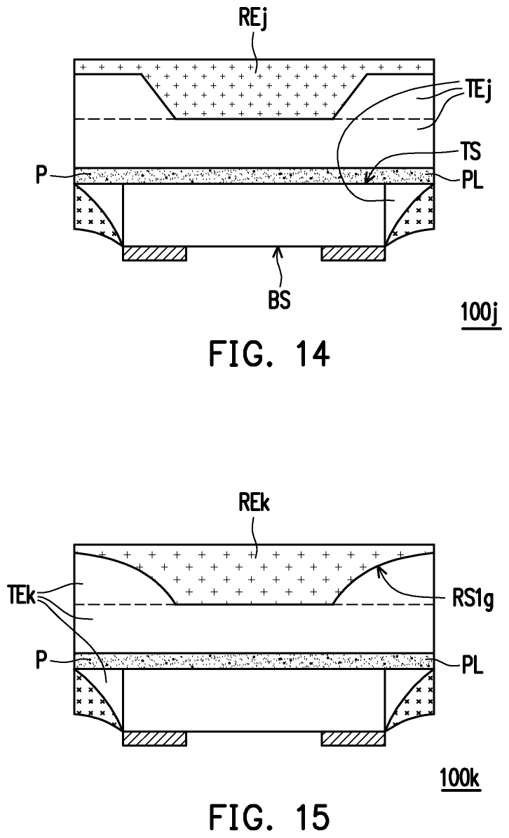

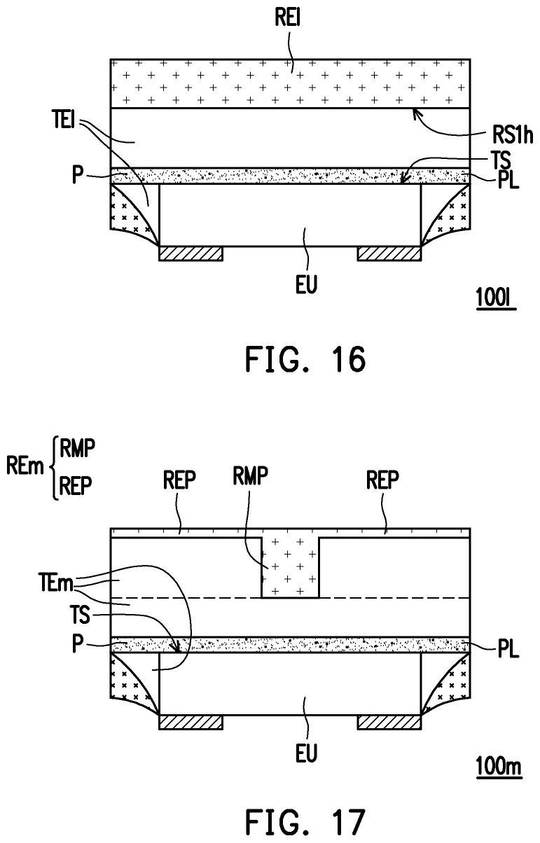

FIG. 14 to FIG. 17 are cross-sectional schematic views of a light emitting device according to still other embodiments of the present invention.

Referring to FIG. 14 to FIG. 17, the light emitting devices 100j-100m of FIG. 14 to FIG. 17 are substantially similar to the light emitting devices 100f-100i of FIG. 9 to FIG. 13 respectively. The reflective members REj-REm of the light emitting devices 100j-100m are respectively identical in form to the reflective members REf-REi of FIG. 9 to FIG. 13, and the major difference is that: in the light emitting devices 100j-100m, a phosphor resin layer PL doped with a phosphor P is further included. The phosphor resin layer PL is disposed on the top surface TS of the light emitting unit EU and is in contact with the light emitting unit EU. The phosphor resin layer PL is located between a part and another part of each of the light transmissive members TEj-TEm. In detail, different parts of each of the light transmissive members TEj-TEm are spaced apart by the phosphor resin layer PL.

Based on the above, in the light emitting devices 100j-100m of the above embodiments, since the phosphor resin layer PL is disposed on the top surface TS of the light emitting unit EU, when the light emitting unit EU emits blue light, a part of the blue light excites the phosphor P in the phosphor resin layer PL to generate yellow light, and the yellow light is combined with the other part of the blue light to emit white light.

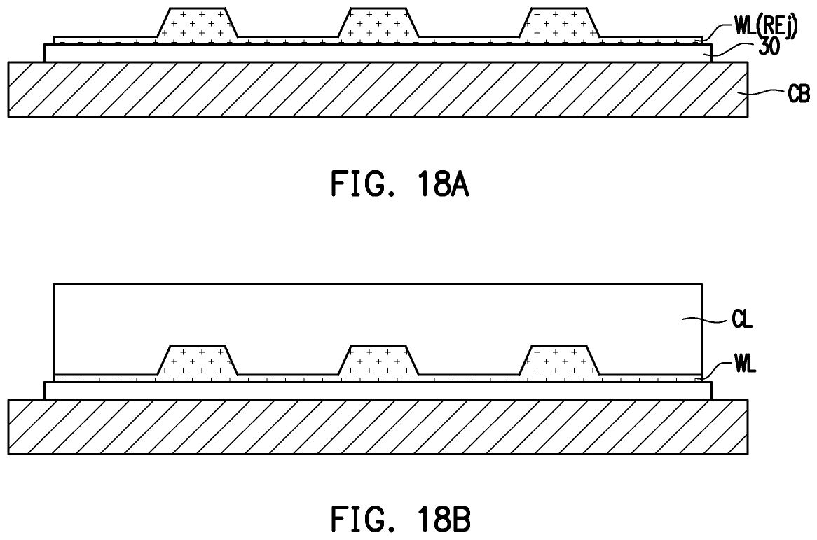

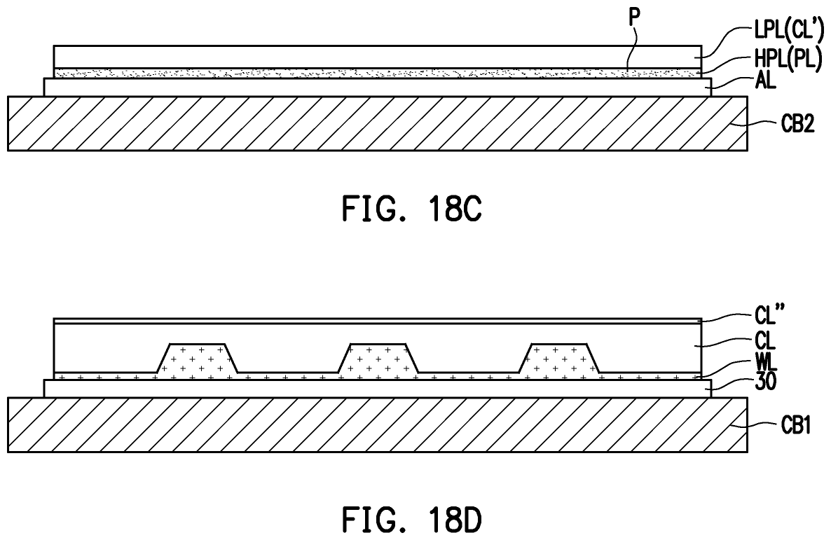

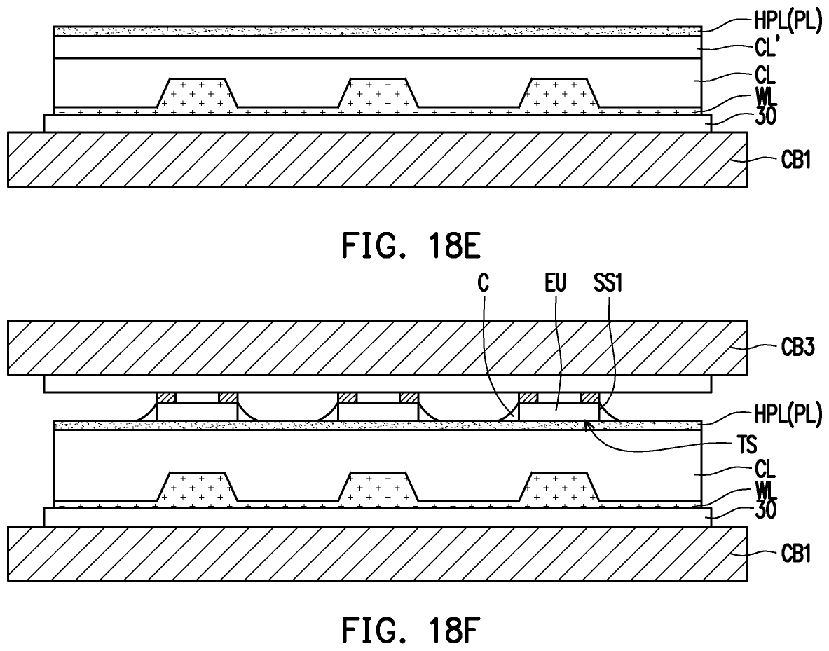

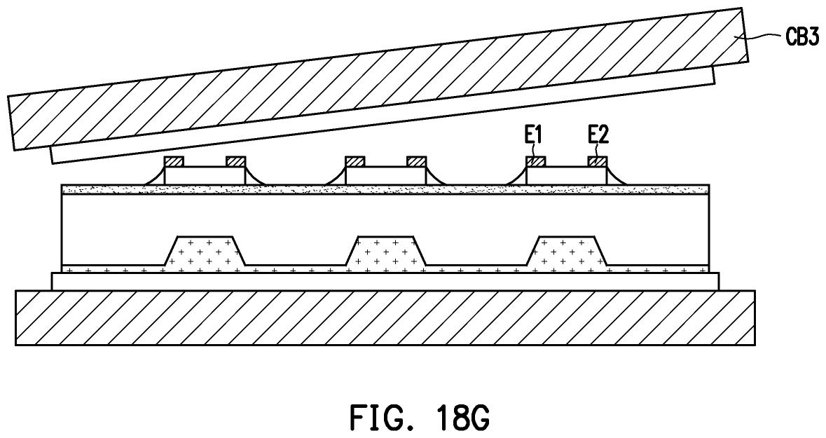

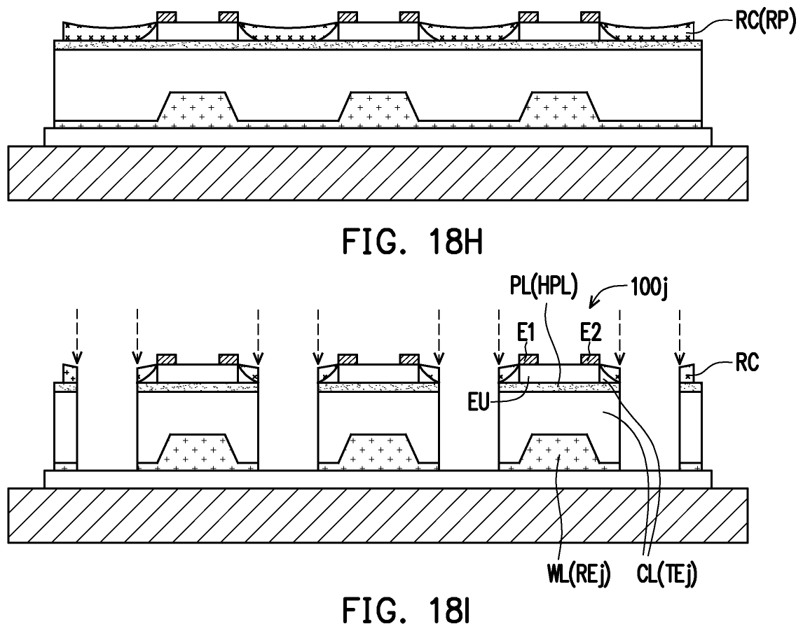

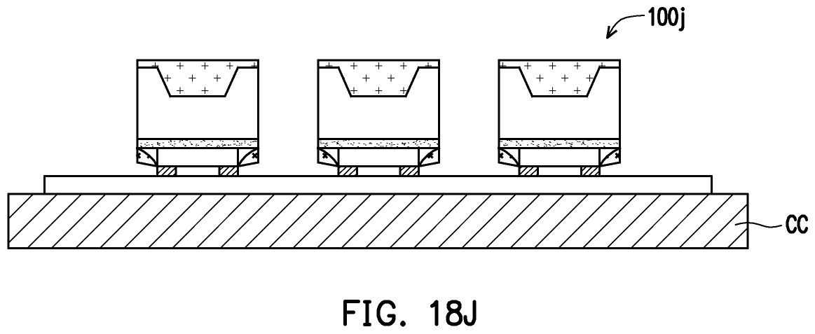

FIG. 18A to FIG. 18J show a manufacturing flow chart for manufacturing the light emitting device of FIG. 14.

Referring to FIG. 18A to FIG. 18B, the steps therein are similar to those in FIG. 13A and FIG. 13B, and the descriptions thereof are omitted herein. The white resin layer WL between the two trapezoidal cuts is served as the reflective member REj of FIG. 14.

Referring to FIG. 18C, a second carrier substrate CB2 is provided, and an adhesive layer AL and a phosphor resin layer are sequentially formed on the second carrier substrate CB2. After the phosphor resin layer is allowed to stand such that the phosphor resin layer is divided into a high-concentration phosphor resin layer HPL and a low-concentration light transmissive resin layer LPL, heating is performed for curing. Since the phosphor concentration of the low-concentration light transmissive resin layer LPL is very low (the phosphor P inside is not shown due to too low concentration), it can be regarded as the light transmissive resin layer CL′, and the high-concentration phosphor resin layer HPL is served as the main body of the phosphor resin layer PL as in FIG. 14.

Referring to FIG. 18D, another light transmissive resin layer CL″ is further formed on the light transmissive resin layer CL in the step of FIG. 18B.

Referring to FIG. 18E, after the light transmissive resin layer CL′ and the high-concentration phosphor resin layer HPL on the second carrier substrate CB2 are transferred to the light transmissive resin layer CL through the adhesion of the light transmissive resin layer CL″ on the first carrier substrate CB1, heating is performed for curing. The second carrier substrate CB2 and the adhesive layer AL are removed.

Referring to FIG. 18F, a plurality of light emitting units EU are provided on the third carrier substrate CB3, and the top surfaces TS of the light emitting units EU are formed into die bonding adhesives C. Then, by bonding the third carrier substrate CB3 loaded with the light emitting units EU to the phosphor resin layer PL, the die bonding adhesive C overflows from two sides of the top surface TS of the light emitting unit EU to cover the lateral surface SS1 of the light emitting unit EU and form a curved surface.

Referring to FIG. 18G, the third carrier substrate CB3 and the bonding layer thereon are removed, and the electrodes E1 and E2 are exposed.

Referring to FIG. 18H, the reflective resin RC fills around the light emitting units EU, the reflective resin RC is allowed to stand to form a curved surface, and the reflective resin RC after standing is heated and baked to be cured so as to be served as a reflective protection member RP.

Referring to FIG. 18I, a cutting process is performed on the baked reflective resins RC, the phosphor resin layer PL, the light transmissive resin layer CL, and the cured white resin layer WL, the reflective resins RC, the high-concentration phosphor resin layer HPL, the low-concentration light transmissive resin layer LPL, the light transmissive resin layer CL, the light transmissive resin layer″, and the white resin layer WL are cut through, and a flat lateral surface is formed to form a plurality of light emitting devices 100j separated from each other. Each of the light emitting devices 100j includes at least one light emitting unit EU, a reflective member RE, a light transmissive member TEf, a phosphor resin layer PL, and a reflective protection member RP. The architecture of the light emitting device 100j is as described in the above paragraphs and the descriptions thereof are omitted herein.

Referring to FIG. 18J, a carrier resin film CC is provided. The carrier substrate CB is inverted to bond the separated light emitting devices 100f to the carrier resin film CC. Thus, the manufacturing of the light emitting device 100f is completed.

In addition, if the light emitting devices 100k-100m are to be manufactured, the manufacturing process is substantially similar to that of the light emitting device 100j, and the major difference is that: in the second scribing process of FIG. 18A, different forms of cutting tools are adopted, or no cutting is performed. For example, if the light emitting device 100k is to be manufactured, an inclined surface cutting knife is adopted. If the light emitting device 100l is to be manufactured, no cutting is performed. If the light emitting device 100m is to be manufactured, a rectangular cutting knife is adopted. Other processes are similar to the manufacturing process of the light emitting device 100k, and the descriptions thereof are omitted herein.

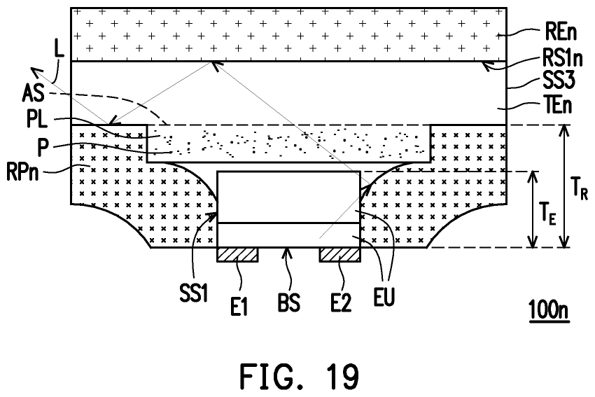

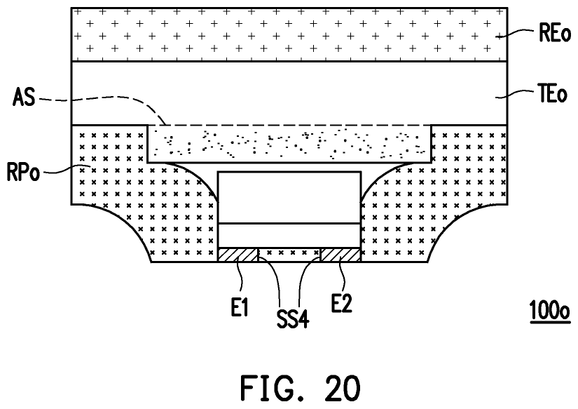

FIG. 19 to FIG. 20 are cross-sectional schematic views of the light emitting device according to still other embodiments of the present invention.

Referring to FIG. 19 first, a light emitting device 100n of FIG. 19 is substantially similar to the light emitting device 100 of FIG. 1. The major difference is that: the thickness T_{R} of a reflective protection member RPn is greater than the thickness T_{E} of the light emitting unit EU. The reflective protection member RPn surrounds the light emitting unit EU and covers the lateral surface SS1 of the light emitting unit EU, and is cut to be aligned with the bottom surface BS of the light emitting unit EU. The reflective protection member RPn has an accommodating space AS inside. The accommodating space AS corresponds to the position of the light emitting unit EU. The form of a reflective surface RS1n of a reflective member REn is a reflective planar surface. Further, the light emitting device 100n further includes a phosphor resin layer PL. The phosphor resin layer PL is disposed in the accommodating space AS.

Further, the reflective surface RS1n of the reflective member REn is a reflective planar surface parallel to the top surface TS of the light emitting unit EU. Further, the light transmissive member TEn is slightly different in shape from the light transmissive member TE because the reflective member REn is different in shape from the reflective member RE of FIG. 1.

Based on the above, in the light emitting device 100n of the present embodiment, the light emitting unit EU is surrounded by the reflective protection member RPn having a larger thickness, and the phosphor resin layer PL is disposed in the accommodating space AS of the reflective protection member RPn corresponding to the light emitting unit EU. Therefore, when the light emitting unit EU emits a light beam L, most of the light beam L is reflected by the reflective protection member RPn surrounding the light emitting unit EU to the phosphor resin layer PL, and is less likely to be dispersed to the outside to be viewed by a user. Therefore, the color of the white light mixed by the light emitting device 100n is relatively uniform. Then, the generated white light is reflected by the reflective surface RS1n of the reflective member REn, and is emitted through the lateral surface SS3 of the light transmissive member TEn.

Referring to FIG. 20, a light emitting device 100o of FIG. 20 is substantially similar to the light emitting device 100n of FIG. 19. The major difference is that: a reflective protection member RPo covers a lateral surface SS4 of the two electrodes E1 and E2 in addition to the lateral surface SS1 of the light emitting unit EU, and is located in a space between the two electrodes E1 and E2.

Further, in other embodiments, the inside of the accommodating space AS may be provided with a light transmissive member rather than the phosphor resin layer, but the present invention is not limited thereto.

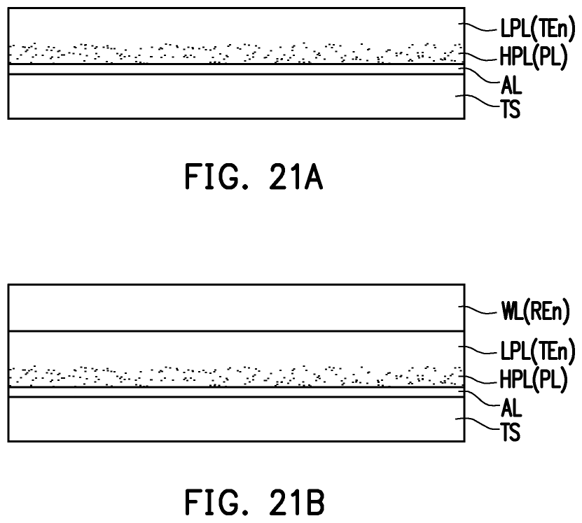

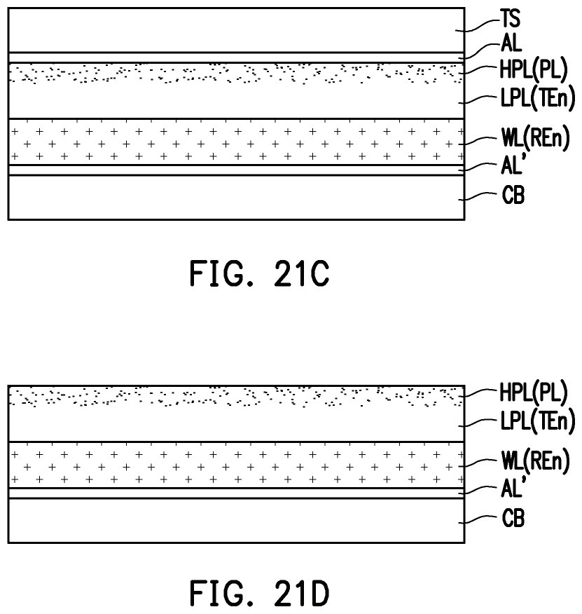

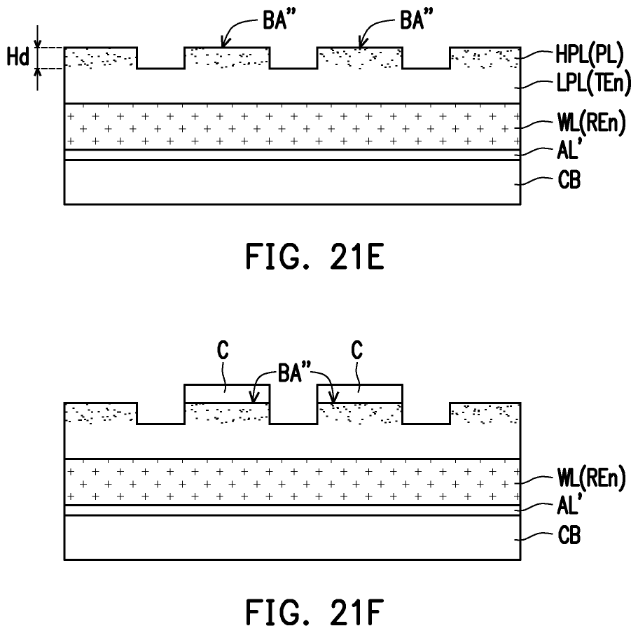

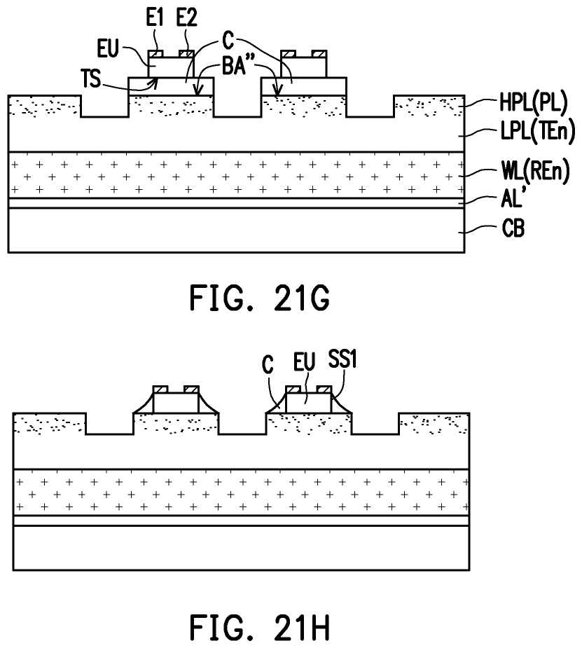

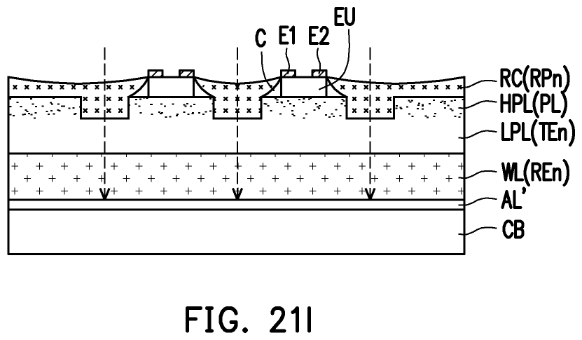

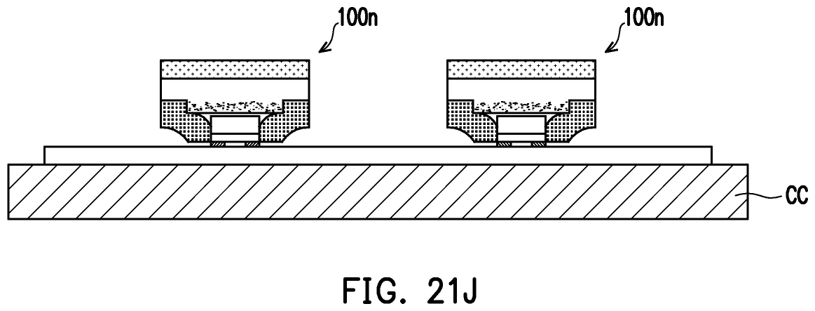

FIG. 21A to FIG. 21J show a manufacturing flow for manufacturing the light emitting device of the embodiment of FIG. 19.

Referring to FIG. 21A, a temporary substrate TS is provided, and an adhesive layer AL and a phosphor resin layer PL are sequentially formed on the temporary substrate TS. The temporary substrate TS may be a glass substrate, a sapphire substrate, a silicon substrate or another substrate of a suitable type, but the present invention is not limited thereto. Then, the phosphor resin layer PL is allowed to stand to be separated into a low-concentration phosphor resin layer LPL and a high-concentration phosphor resin layer HPL. The concentration of phosphor P increases from the low-concentration phosphor resin layer LPL to the high-concentration phosphor resin layer HPL. Then, the phosphor resin layer PL is heated and cured. The low-concentration phosphor resin layer LPL can be served as the light transmissive member TEn as in FIG. 19 because of the low ratio of the phosphor P, and the high-concentration phosphor resin layer HPL can be served as the main body of the phosphor resin layer PL as in FIG. 19.

Referring to FIG. 21B, a white resin layer WL is formed on the low-concentration phosphor resin layer LPL. The white resin layer WL can be served as the reflective member REn as in FIG. 19.

Referring to FIG. 21C, a carrier substrate CB is provided. Another adhesive layer AL′ is formed on the surface of the carrier substrate CB. The temporary substrate TS loaded with the phosphor resin layer PL and the white resin layer WL is transferred and bonded to the adhesive layer AL′ of the carrier substrate CB.

Referring to FIG. 21D, the temporary substrate TS and the adhesive layer AL are removed, and the high-concentration phosphor resin layer HPL is exposed to the outside.

Referring to FIG. 21E, a scribing process is performed on the high-concentration phosphor resin layer HPL to define a plurality of bonding areas BA″ (or referred to as platform areas). The depth Hd of cutting may be, for example, less than 1000 micrometers, but is not limited thereto. In the present embodiment, a tool used for the scribing process is, for example, a rectangular tool, so that a notch scribed in the high-concentration phosphor resin layer HPL can be, for example, a rectangular notch. In other embodiments, an arc tool may also be used to scribe an arc-shaped notch.

Referring to FIG. 21F, a plurality of die bonding adhesives C (materials including, but not limited to, transparent glue) are respectively provided on the bonding areas BA″.

Referring to FIG. 21G, a plurality of light emitting units EU are provided, and the top surface TS of each of the light emitting units EU is bonded to the corresponding bonding area BA″ through the die bonding adhesive C, such that the two electrodes E1 and E2 are exposed to the outside.

Referring to FIG. 21H, a pressurization process is performed, such that the die bonding adhesive C overflows from two sides of the top surface TS of the light emitting unit EU and covers the lateral surface SS1 of the light emitting unit EU. Next, a heating process is performed, such that the die bonding adhesive C is cured.

Referring to FIG. 21I, a reflective resin RC fills around the light emitting units EU to cover the lateral surfaces SS1 of the light emitting units EU, and the reflective resin RC is heated and baked. The baked reflective resin RC can be served as the reflective protection member RPo as in FIG. 19.

Referring to FIG. 21J, a second cutting process is performed on the baked reflective resins RC (reflective protection members RPn), the high-concentration phosphor resin layer HPL (phosphor resin layer PL), the low-concentration phosphor resin layer LPL (light transmissive member TEn), and the cured white resin layer WL (reflective member REn) to form a plurality of light emitting devices 100n separated from each other. Each of the light emitting devices 100n includes at least one light emitting unit EU, a reflective member REn, a light transmissive member TEn, a phosphor resin layer PL, and a reflective protection member RPn. The architecture of the light emitting device 100n is as described in the above paragraphs, and the descriptions thereof are omitted herein.

Referring to FIG. 21K, a carrier resin film CC is provided. The carrier substrate CB is inverted to bond the separated light emitting devices 100n to the carrier resin film CC. Thus, the manufacturing of the light emitting device 100n is completed.

In addition, if the light emitting device 100o is to be manufactured, the manufacturing process thereof is substantially similar to that of the light emitting device 100n, and the major difference is that: in the step of filling with the reflective resin RC in FIG. 21I, the filling amount of the reflective resin RC is increased, such that the reflective resin RC covers the lateral surface SS4 of the two electrodes E1 and E2 and is located in the space between the two electrodes E1 and E2. Other processes are similar to the manufacturing process of the light emitting device 100n, and the descriptions thereof are omitted herein.

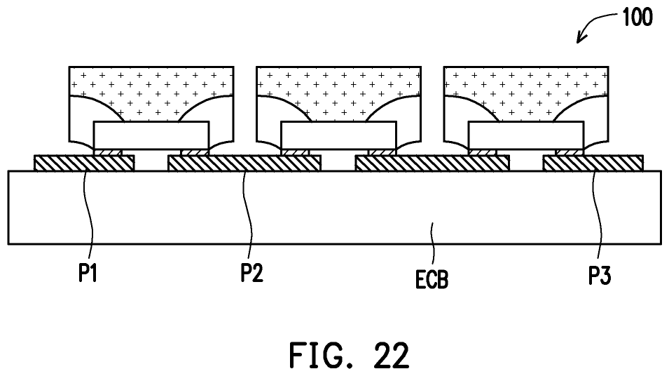

FIG. 22 is a schematic view showing the connection of a light emitting device of an embodiment of the present invention and a circuit substrate.

Referring to FIG. 22, the light emitting device 100 of the embodiments of the present invention can be mounted on the circuit substrate ECB through pads P1, P2 and P3 in series, parallel, or series-parallel. It should be noted that one or more implementations of the light emitting devices 100a-100o of other embodiments may also be selected and mounted on the circuit substrate ECB in a similar manner, and the present invention is not limited thereto.

Based on the above, in the light emitting device according to the embodiments of the present invention, since the reflective member and the two electrodes are respectively disposed on two opposite sides of the light emitting unit and the light transmissive member covers a part of the light emitting unit, after the light emitting unit emits a light beam, the light beam is reflected by the reflective surface of the reflective member to be emitted to the lateral surface of the light transmissive member. Therefore, the light emitting device can have the effect of lateral light emission, which can avoid the problem of light spots and have good applicability in different fields. Further, since a part of the light emitting unit is covered by the light transmissive member and is not in contact with air, the light emitting device can have a large light emitting angle. Further, in the manufacturing method of the light emitting device according to the embodiments of the present invention, since the top surface of the light emitting unit is bonded to the reflective resin layer and the lateral surface of the light emitting unit is covered by the light transmissive resin layer, the light emitting device manufactured by the above manufacturing method can avoid the problem of light spots and have a large light emitting angle.

Although the invention is described with reference to the above embodiments, the embodiments are not intended to limit the invention. A person of ordinary skill in the art may make variations and modifications without departing from the spirit and scope of the invention. Therefore, the protection scope of the invention should be subject to the appended claims.

1. A light emitting device, comprising:
a light emitting unit comprising a first side and a second side opposite to each other;
a plurality of electrodes disposed on the first side, wherein the electrodes are electrically connected to the light emitting unit;
a reflective member disposed on the second side, wherein the reflective member comprises at least one reflective surface; and
a light transmissive member disposed between the reflective member and the light emitting unit, and covering a part of the light emitting unit, wherein a lateral surface of the light transmissive member is served as a light emitting surface of the light emitting device.

2. The light emitting device according to claim 1, wherein the light transmissive member comprises a first light transmissive portion and a second light transmissive portion, the first light transmissive portion is located between the reflective member and the second light transmissive portion, the second light transmissive portion is located between the first light transmissive portion and the light emitting unit, and lateral surfaces of the first light transmissive portion and the second light transmissive portion together are served as the lateral surface of the light transmissive member.

3. The light emitting device according to claim 2, wherein the light transmissive member further comprises a third light transmissive portion, the first light transmissive portion and the second light transmissive portion cover a top surface of the light emitting unit, and the third light transmissive portion covers a lateral surface of the light emitting unit.

4. The light emitting device according to claim 3, further comprising a reflective protection member, disposed beside the third light transmissive portion, wherein the reflective protection member comprises a reflective curved surface.

5. The light emitting device according to claim 3, wherein the second light transmissive portion is connected to the third light transmissive portion.

6. The light emitting device according to 1, further comprising a phosphor resin layer, covering a top surface of the light emitting unit, wherein the phosphor resin layer is located between a part and another part of the light transmissive member.

7. The light emitting device according to claim 1, further comprising:
a reflective protection member, surrounding the light ei ing unit and covering a lateral surface of the light emitting unit, wherein the thickness of the reflective protection member is greater than the thickness of the light emitting unit.

8. The light emitting device according to claim 7, further comprising a phosphor resin layer, wherein the reflective protection member comprises an accommodating space, the accommodating space corresponds to the light emitting unit, the phosphor resin layer is disposed in the accommodating space, and the light transmissive member is disposed between the reflective member and the phosphor resin layer.

9. The light emitting device according to claim 1, wherein the light transmissive member comprises a phosphor.

10. The light emitting device according to claim 1, wherein the reflective surface is a reflective inclined surface, a reflective curved surface, a reflective planar surface, or a combination thereof.

11. The light emitting device according to claim 1, wherein the light transmissive member covers at least a part of a top surface and a lateral surface of the light emitting unit.

12. A manufacturing method of a light emitting device, comprising:
forming a reflective resin layer;
providing a plurality of light emitting units, wherein a bottom surface of each of the light emitting units is provided with a plurality of electrodes;
bonding a plurality of top surfaces of the light emitting units respectively to the reflective resin layer;
forming a light transmissive resin layer, and enabling the light transmissive resin layer to cover a plurality of lateral surfaces of the light emitting units; and
performing a cutting process on the reflective resin layer and the light transmissive resin layer to form a plurality of light emitting devices, wherein each of the light emitting devices comprises at least one of the light emitting units.

13. The manufacturing method of the light emitting device according to claim 12, wherein after the step of forming the reflective resin layer, the manufacturing method further comprises:
performing a scribing process on the reflective resin layer to form a plurality of first grooves in the reflective resin layer, such that the reflective resin layer is divided into a plurality of bonding areas.

14. The manufacturing method of the light emitting device according to claim 13, wherein in the step of bonding the top surfaces of the light emitting units respectively to the reflective resin layer, the top surfaces are respectively bonded to the bonding areas of the reflective resin layer.

15. The manufacturing method of the light emitting device according to claim 13, wherein in the step of forming the light transmissive resin layer, the manufacturing method further comprises:
providing a light transmissive resin in the first grooves, and covering the lateral surfaces of the light emitting units; and
curing the light transmissive resin to form the light transmissive resin layer.

16. The manufacturing method of the light emitting device according to claim 13, wherein in the step of performing the cutting process on the reflective resin layer and the light transmissive resin layer, the manufacturing method further comprises:
performing the cutting process on the reflective resin layer and the light transmissive resin layer along the first grooves.

17. The manufacturing method of the light emitting device according to claim 13, wherein the cross-sectional shape of the first grooves is an arc shape, a trapezoidal shape, a straight line, or a combination thereof.

18. The manufacturing method of the light emitting device according to claim 13, wherein in the step of forming the light transmissive resin layer, the manufacturing method further comprises:
providing a plurality of first light transmissive resins on the top surfaces of the light emitting units.

19. The manufacturing method of the light emitting device according to claim 18, wherein in the step of bonding the top surfaces of the light emitting units respectively to the reflective resin layer, the top surfaces are respectively bonded to the bonding areas of the reflective resin layer through the first light transmissive resins, wherein the first light transmissive resins cover a partial surface of the reflective resin layer.

20. The manufacturing method of the light emitting device according to claim 19, wherein in the step of forming the light transmissive resin layer, the manufacturing method further comprises:
providing a plurality of second light transmissive resins around the light emitting units, and enabling the second light transmissive resins to cover the lateral surfaces of the light emitting units; and
curing the first light transmissive resins and the second light transmissive resins to form the light transmissive resin layer.

21-35. (canceled)
